(19) United States
(12) Patent Application Publication
(10) Pub. No.: US 2025/0169077 A1
(43) Pub. Date: May 22, 2025

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventor: Ki Joon KIM, Suwon-si (KR)

(21) Appl. No.: 18/663,210

(22) Filed: May 14, 2024

(30) Foreign Application Priority Data
Nov. 20, 2023 (KR) 10-2023-0160358

(51) Int. Cl. H10B 51/20; H10B 51/30

(52) U.S. Cl. CPC H10B 51/20; H10B 51/30

(57) ABSTRACT

A semiconductor device includes a cell substrate; a mold structure which includes gate electrodes and mold insulating films alternately stacked on the cell substrate; a channel layer that extends in a vertical direction intersecting an upper side of the cell substrate, inside the mold structure; an insertion layer which includes ferroelectrics and surrounds the channel layer; and a dielectric layer which is not interposed between the insertion layer and the gate electrodes, but is interposed between the insertion layer and the mold insulating films, wherein the gate electrodes are in contact with the insertion layer.

This application claims the benefit of Korean Patent Application No. 10-2023-0160358, filed on Nov. 20, 2023, in the Korean Intellectual Property Office, the disclosure of which is incorporated herein in its entirety by reference.

### TECHNICAL FIELD

The present disclosure relates to a semiconductor memory device and an electronic system including the same. More specifically, the present disclosure relates to a semiconductor memory device including three-dimensionally arranged memory cells and an electronic system including the same.

### BACKGROUND

An integration density of nonvolatile memory devices is increasing in order to satisfy requirements driven by electronic systems, technologies for increasing the data storage capacity are being researched. In a two-dimensional or planar memory device, the integration density is determined based on an area occupied by a unit memory cell. Accordingly, a three-dimensional memory device, in which unit memory cells are vertically arranged, has been proposed.

### SUMMARY

Aspects of the present disclosure provide a semiconductor memory device having improved characteristics.

Aspects of the present disclosure provide an electronic system including a semiconductor memory device having improved degree of integration and memory capacity.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a semiconductor device includes a substrate, a mold stack which includes gate electrodes and mold insulating films alternately stacked on the substrate, a channel layer that extends through the mold stack in a vertical direction intersecting an upper surface of the substrate, and an insertion layer the channel layer. The insertion layer includes ferroelectrics and surrounds. The semiconductor device further includes a dielectric layer which is interposed between the insertion layer and the mold insulating films. The gate electrodes are in contact with the insertion layer.

According to another aspect of the present disclosure, a semiconductor device includes a substrate, a mold stack which includes gate electrodes and mold insulating films alternately stacked on the substrate, a channel layer which extends through the mold stack in a vertical direction intersecting an upper surface of the substrate, and an insertion layer which includes an extension part extending in the vertical direction along a side face of the channel layer and a plurality of protrusion parts protruding from the extension part toward the gate electrodes. The extension part and the plurality of protrusion parts each include a ferroelectric material.

According to another aspect of the present disclosure, electronic system includes a main board, a semiconductor memory device on the main board, and a controller which is electrically connected to the semiconductor memory device. The controller is disposed on the main board. The semiconductor memory device includes a substrate, a mold stack which includes gate electrodes and mold insulating films alternately stacked on the substrate, a channel layer which extends through the mold stack in a vertical direction intersecting an upper surface of the substrate, and an insertion layer which surrounds the channel layer. The insertion layer includes ferroelectrics. The semiconductor memory device further includes a dielectric layer which is interposed between the insertion layer and the mold insulating films. The gate electrodes are in contact with the insertion layer.

### BRIEF DESCRIPTION OF THE DRAWINGS

The above and other aspects and features of the present disclosure will become more apparent from the following detailed description taken in conjunction with the attached drawings, in which:

FIG. 1 is an exemplary block diagram for explaining a semiconductor memory device according to some embodiments;

FIG. 2 is an exemplary circuit diagram for explaining a semiconductor memory device according to some embodiments;

FIG. 3 is a schematic layout diagram for explaining a semiconductor memory device according to some embodiments;

FIG. 4 is a cross-sectional view taken along a line A-A of FIG. 3;

FIG. 5 is an enlarged view for explaining a region R of FIG. 4;

FIGS. 6 to 13 are enlarged views for explaining the region R of FIG. 4;

FIGS. 14 to 26 are cross-sectional views illustrating a method of manufacturing a semiconductor memory device in accordance with some embodiments;

FIG. 27 is a cross-sectional view illustrating a method of manufacturing a semiconductor memory device in accordance with some embodiments;

FIGS. 28 to 31 are cross-sectional views illustrating a method of manufacturing a semiconductor memory device in accordance with some embodiments;

FIGS. 32 and 33 are enlarged views for explaining the region R of FIG. 4;

FIGS. 34 to 38 are cross-sectional views illustrating a method of manufacturing a semiconductor memory device in accordance with some embodiments;

FIGS. 39 and 40 are cross-sectional views illustrating a method of manufacturing a semiconductor memory device in accordance with some embodiments;

FIG. 41 is a cross-sectional view illustrating a method of manufacturing a semiconductor memory device in accordance with some embodiments;

FIG. 42 is an example block diagram for explaining an electronic system according to some embodiments;

FIG. 43 is an exemplary perspective view for explaining the electronic system according to some embodiments; and

FIG. 44 is a schematic cross-sectional view taken along line I-I of FIG. 43.

### DETAILED DESCRIPTION OF THE EMBODIMENTS

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. In other instances, well-known methods, procedures, components, and circuits have not been described in detail so as not to unnecessarily obscure aspects of the present disclosure.

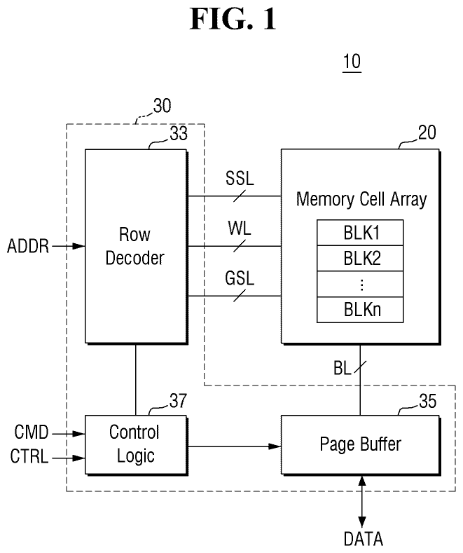

FIG. 1 is an exemplary block diagram for explaining a semiconductor memory device according to some embodiments.

Referring to FIG. 1, a semiconductor memory device 10 according to some embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL and the ground selection line GSL. Further, the memory cell blocks BLK1 to BLKn may be connected to a page buffer 35 through the bit line BL.

The peripheral circuit 30 may receive an address ADDR, a command CMD and a control signal CTRL from the outside of the semiconductor memory device 10, and may transmit and receive data DATA to and from an external device of the semiconductor memory device 10. The peripheral circuit 30 may include a control logic 37, a row decoder 33 and a page buffer 35. Although not shown, the peripheral circuit 30 may further include various sub-circuits, such as an input/output (I/O) circuit, a voltage generation circuit that generates various voltages necessary for the operation of the semiconductor memory device 10, and an error correction circuit for correcting error of the data DATA that is read from the memory cell array 20.

The control logic 37 may be connected to the row decoder 33, the input/output circuit and the voltage generation circuit. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word line WL and the bit line BL when performing a memory operation such as a program operation or an erase operation. It should be noted that items described in the singular herein, may be provided in plural, as can be seen in the various figures from the context in which they are described.

The row decoder 33 may select at least one of the plurality of memory cell blocks BLK1 to BLKn in response to the address ADDR, and may select at least one word line WL, at least one string selection line SSL, and at least one ground selection line GSL of the selected one of the memory cell blocks BLK1 to BLKn. The row decoder 33 may transfer a voltage for performing the memory operation to the word lines WL of the selected one of the memory cell blocks BLK1 to BLKn.

The page buffer 35 may be connected to the memory cell array 20 through the bit line BL. The page buffer 35 may operate as a write driver or a sense amplifier. Specifically, when performing the program operation, the page buffer 35 may operate as the write driver to apply a voltage according to the data DATA to be stored in the memory cell array 20 to the bit line BL. On the other hand, when performing the read operation, the page buffer 35 may operate as a sense amplifier to sense the data DATA stored in the memory cell array 20.

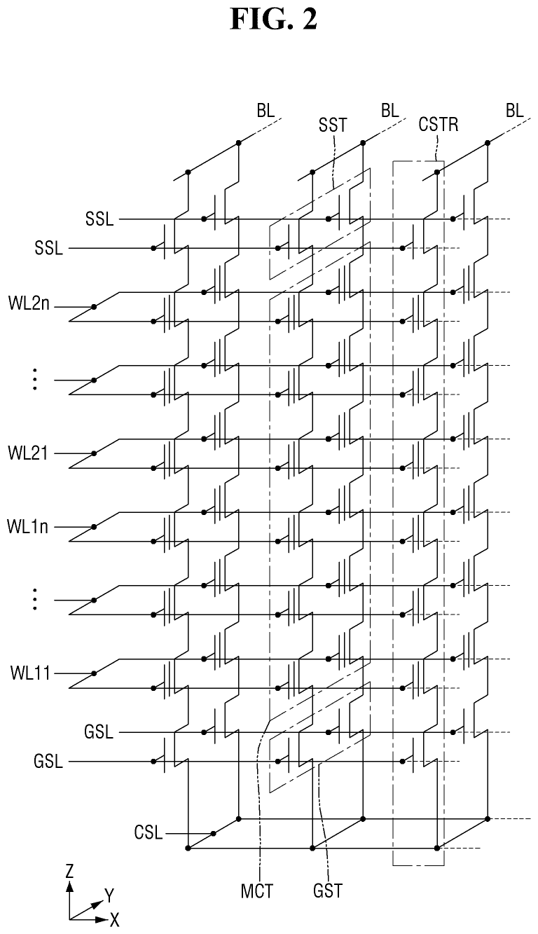

FIG. 2 is an exemplary circuit diagram for explaining a semiconductor memory device according to some embodiments.

Referring to FIG. 2, a memory cell array (e.g., 20 of FIG. 1) of the semiconductor device according to some embodiments may include a common source line CSL, the bit lines BL and a plurality of cell strings CSTR.

The plurality of bit lines BL may be arranged two-dimensionally in a plane parallel to an X-Y plane (i.e., a plane extending along a first direction X and a second direction Y).

For example, the bit lines BL are spaced apart from each other and arranged along the first direction X, and may each extend in the second direction Y. The plurality of cell strings CSTR may be connected in parallel to each bit line BL. The cell strings CSTR may be commonly connected to the common source line CSL. The plurality of cell strings CSTR may be disposed between the bit lines BL and the common source line CSL.

Each cell string CSTR may include a ground selection transistor GST connected to the common source line CSL, a string selection transistor SST connected to the bit line BL, and a plurality of memory cell transistors MCT disposed between the ground selection transistor GST and the string selection transistor SST. Each memory cell transistor MCT may include a data storage element. The ground selection transistor GST, the string selection transistor SST and the memory cell transistors MCT may be connected in series.

The common source line CSL may be commonly connected to sources of the ground selection transistors GST. Also, the ground selection line GSL, the plurality of word lines WL11 to WL1n and WL21 to WL2n (also designated collectively as WL in FIG. 1), and the string selection line SSL may be disposed between the common source line CSL and the bit line BL. The ground selection line GSL may be used as a gate electrode of the ground selection transistor GST, the word lines WL11 to WL1n and WL21 to WL2n may be used as gate electrodes of the memory cell transistors MCT, and the string selection line SSL may be used as the gate electrode of the string selection transistor SST.

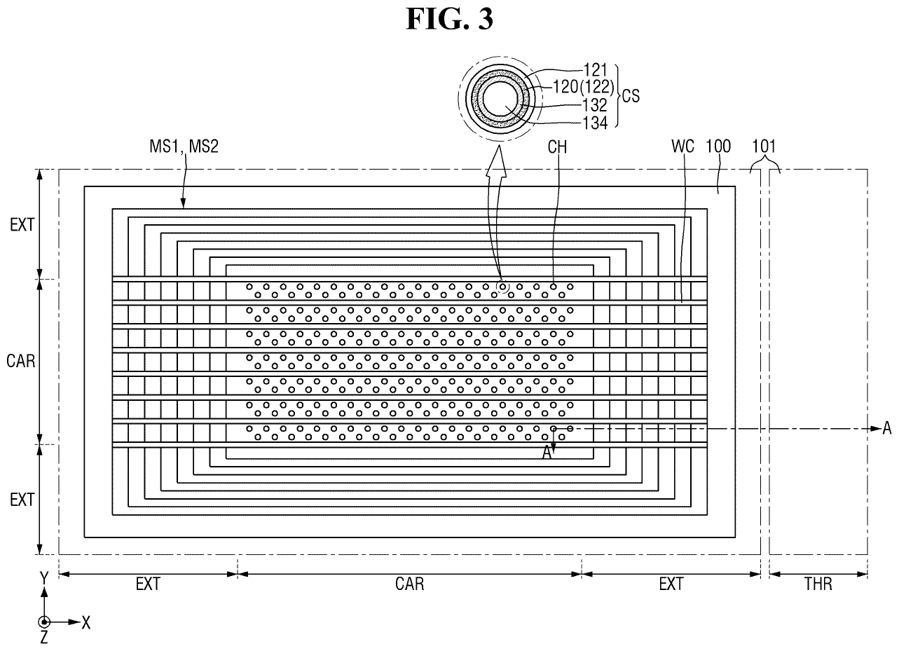

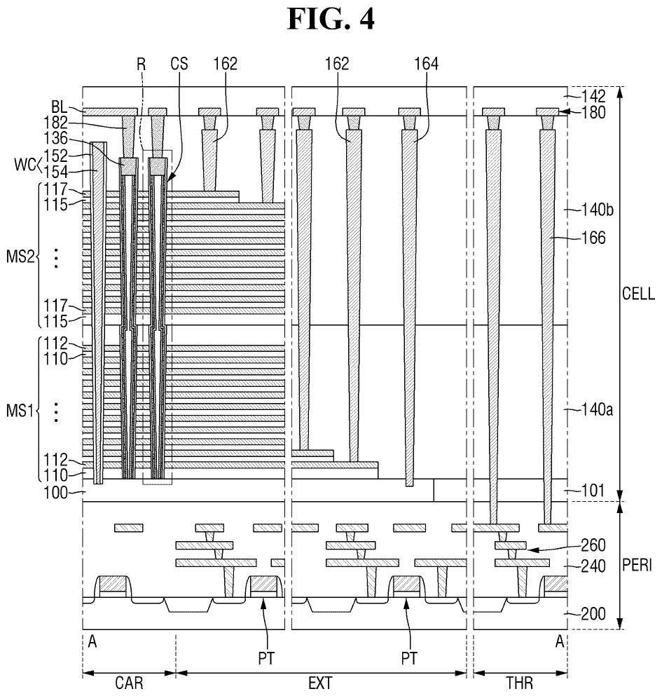

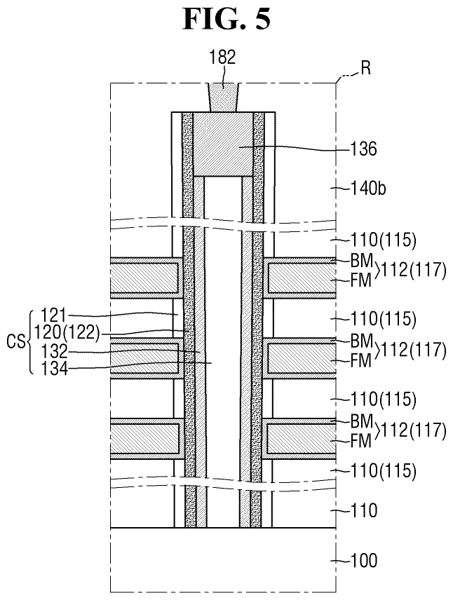

FIG. 3 is a schematic layout diagram for explaining a semiconductor memory device according to some embodiments. FIG. 4 is a cross-sectional view taken along line A-A of FIG. 3. FIG. 5 is an enlarged view for explaining the region R of FIG. 4.

Referring to FIGS. 3 to 5, the semiconductor memory device according to some embodiments includes a cell structure CELL and a peripheral circuit structure PERI.

The cell structure CELL may include a cell substrate 100, an insulating substrate 101, first and second mold stacks MS1 and MS2, interlayer insulating films 140a and 140b (also described as “a first interlayer insulating film 140a” and “a second interlayer insulating film 140b”), a channel structure CS, a word line cutting region WC, the bit line BL, a gate contact 162, and a cell wiring structure 180.

The cell substrate 100 may include a semiconductor substrate, for example, such as a silicon substrate, a germanium substrate or a silicon-germanium substrate. Alternatively, the cell substrate 100 may include a silicon-on-insulator (SOI) substrate, a germanium-on-insulator (GOI) substrate, or the like.

In some embodiments, the cell substrate 100 may include impurities. For example, the cell substrate 100 may include N-type impurities (e.g., phosphorus (P) or arsenic (As)). In the following description, although the cell substrate 100 will be mainly described as being of N type, this is merely an example, and in some embodiments, the cell substrate 100 may be of P type. In some embodiments, the cell substrate 100 may include polysilicon (poly-Si) doped with N-type impurities. Such a cell substrate 100 may be provided as a common source line (e.g., CSL of FIG. 2) of a semiconductor memory device according to some embodiments.

The cell substrate 100 may include a cell array region CAR, an extension region EXT and a through region THR.

The memory cell array (e.g., 20 of FIG. 1) including a plurality of memory cells may be formed on the cell array region CAR. For example, a channel structure CS, gate electrodes 112 and 117, a bit line BL, and the like, which will be described later in detail, may be disposed on the cell array region CAR. In the following description, a surface of the cell substrate 100 on which the memory cell array is disposed may be referred to as a front side. In contrast, a surface of the cell substrate 100 opposite to the front side of the cell substrate 100 may be referred to as a back side of the cell substrate 100. The front side and the backside are parallel to the X-Y plane.

The extension region EXT may be disposed around the cell array region CAR. For example, the extension region EXT may surround the cell array region CAR in a plan view. The gate electrodes 112 and 117, which will be described below, may be stacked on the extension region EXT in a stepwise manner.

The through region THR may be disposed outside the cell array region and/or extension region EXT, or may be disposed inside the cell array region and/or the extension region EXT. A through plug 166, which will be described below, may be disposed on the through region THR.

The insulating substrate 101 may be formed in at least a part of the cell substrate 100 in the extension region EXT and/or the penetration region THR. The insulating substrate 101 may be an insulating region in the cell substrate 100 in the extension region EXT and/or the penetration region THR. As an example, the insulating substrate 101 may be formed by replacing at least a part of the cell substrate 100 in the through region THR to define the insulating region in the through region THR. The insulating substrate 101 may include, for example, but is not limited thereto, at least one of silicon oxide, silicon nitride, silicon oxynitride and silicon carbide.

The first and second mold stacks MS1 and MS2 may be formed on the cell substrate 100. The first and second mold stacks MS1 and MS2 may include the gate electrodes 112 and 117 and a plurality of first and second mold insulating films (also, collectively described as mold insulating films) 110 and 115 that are stacked on the cell substrate 100. Each of the gate electrodes 112 and 117 and each of the mold insulating films 110 and 115 may have a layered structure extending parallel to the upper side (i.e., front side) of the cell substrate 100. The gate electrodes 112 and 117 are spaced apart from each other by the mold insulating films 110 and 115, and may be sequentially stacked on the cell substrate 100. Hereinafter, the upper side and the lower side (also referred to as “the upper surface and the lower surface”) of the cell substrate 100 are defined on the basis of a third direction Z, and refer to the front side and the back side of the cell substrate 100, respectively. Similarly, the term “upper” side or surface of an element is defined on the basis of the third direction Z. Therefore, the term “lower” side or surface of the element refers to an opposite side or surface of the element to the “upper” side or surface of the element. The third direction Z is perpendicular to the X-Y plane. Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures.

The first and second mold stacks MS1 and MS2 may be stacked sequentially on the cell substrate 100. Although the number of stacks stacked on the cell substrate 100 is only shown as two, this is only for convenience of explanation, and in some embodiments, the number of stacks stacked on the cell substrate 100 may be three or more. In some embodiments, the semiconductor memory device may have only one mold stack.

The first mold stack MS1 may include first mold insulating films 110 and first gate electrodes 112 that are alternately stacked on the cell substrate 100. In some embodiments, the first gate electrodes 112 may function as at least a part of the ground selection line (e.g., GSL of FIG. 2) and at least a part of the first word lines (e.g., WL11 to WL1n of FIG. 2) that are stacked sequentially on the cell substrate 100. The number, placement, and the like of the first mold insulating film 110 and the first gate electrode 112 are merely exemplary, and are not limited to those shown. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The second mold stack MS2 may include second mold insulating films 115 and second gate electrodes 117, which are alternately stacked on the first mold stack MS1. In some embodiments, the second gate electrodes 117 may function as at least a part of the second word lines (e.g., WL21 to WL2n of FIG. 2) and at least a part of the string selection line (e.g., SSL of FIG. 2) that are stacked sequentially on the first mold stack MS1. The number, placement, and the like of the second mold insulating films 115 and the second gate electrodes 117 are merely exemplary, and are not limited to those shown.

The gate electrodes 112 and 117 may each include or be formed a conductive material, for example, but not limited to, a metal such as tungsten (W), molybdenum (Mo), ruthenium (Ru), cobalt (Co), nickel (Ni), or a semiconductor material such as silicon. As an example, the gate electrodes 112 and 117 may each include or be formed of at least one of tungsten (W), molybdenum (Mo) and ruthenium (Ru). As another example, the gate electrodes 112 and 117 may each include or be formed of polysilicon.

In some embodiments, each of the gate electrodes 112 and 117 may include a barrier metal film (BM) and a filling metal film (FM). The barrier metal film BM may conformally extend along the upper and lower sides of the mold insulating films 110 and 115, and a side face of a dielectric layer 121. The filling metal film FM may fill regions of the gate electrodes 112 and 117 that remain after the barrier metal film BM is filled. The term “conformal” and derivations thereof (for instance, “conformally”) describes a film, a layer or a coating material in which angles of the underlying material are preserved. For purposes of interpreting this disclosure and the claims, the term is to be understood to be indicated by a substantially uniform thickness down a vertical profile, and/or by a substantially uniform thickness along an interface where a substantially vertical profile joins a substantially horizontal profile, but is not limited to layers having perfectly uniform thickness.

Each of the mold insulating films 110 and 115 may include, for example, but not limited to, at least one of silicon oxide, silicon nitride and silicon oxynitride. As an example, the mold insulating films 110 and 115 may each include or be a silicon oxide film.

The interlayer insulating films 140a and 140b may be formed on the front side of the cell substrate 100 to cover the first and second mold stacks MS1 and MS2. In some embodiments, the first interlayer insulating film 140a and the second interlayer insulating film 140b may be sequentially stacked on the cell substrate 100. The first interlayer insulating film 140a may cover the first mold stack MS1, and the second interlayer insulating film 140b may cover the second mold stack MS2. The interlayer insulating films 140a and 140b may include, for example, but are not limited to, at least one of silicon oxide, silicon oxynitride, and a low-k material having a dielectric constant lower than that of silicon oxide.

The channel structure CS may be formed on the cell array region CAR of the cell substrate 100. The channel structure CS extends in the vertical direction (i.e., the third direction Z) intersecting the upper side of the cell substrate 100 through the first and second mold stacks MS1 and MS2. The channel structure CS may penetrate the first and second mold stacks MS1 and MS2. For example, the channel structure CS may have a pillar shape (for example, a cylindrical shape) extending in the third direction Z. Therefore, the channel structure CS may intersect the plurality of gate electrodes 112 and 117.

In some embodiments, the channel structure CS may have a step between the first mold stack MS1 and the second mold stack MS2. For example, as shown in FIG. 4, the side faces of the channel structure CS may be bent at an interface between the first mold stack MS1 and the second mold stack MS2.

The channel structure CS includes an insertion layer 120, the dielectric layer 121, a channel layer 132 and a core insulating layer 134. The channel layer 132 may be formed of or include ferroelectrics.

The core insulating layer 134 extends in the third direction Z. The core insulating layer 134 may have, for example, a pillar shape. The core insulating layer 134 may include or be formed of, for example, at least one of silicon oxide, silicon nitride and silicon oxynitride, but is not limited thereto. As an example, the core insulating layer 134 may be silicon oxide.

The channel layer 132 may surround the core insulating layer 134. The channel layer 132 extends in the third direction Z and intersects the plurality of gate electrodes 112 and 117. For example, the channel layer 132 may extend conformally along an outer side of the core insulating layer 134. The channel layer 132 may extend through the mold stack MS1 and MS2 in the vertical direction intersecting the upper side of the cell substrate 100.

One end of the channel layer 132 may be electrically connected to a common source line (e.g., CSL of FIG. 2). As an example, if the cell substrate 100 is provided as a common source line, one end of the channel layer 132 may be connected to the cell substrate 100. In FIGS. 4 and 5, although the lower side of the channel layer 132 is only shown as being disposed on the same plane as the upper side of the cell substrate 100, this is merely an example. As another example, a lower part of the channel layer 132 may be buried inside the cell substrate 100, and the lower side of the channel layer 132 may be disposed to be lower than the upper side of the cell substrate 100.

The channel layer 132 may be formed of or include semiconductor materials such as, but not limited to, single crystal silicon, polycrystalline silicon, organic semiconductor matters, carbon nanostructures, and the like.

The insertion layer 120 surrounds the channel layer 132. In the semiconductor memory device according to some embodiments, the insertion layer 120 includes a first ferroelectric layer 122. The first ferroelectric layer 122 may surround the channel layer 132. For example, the first ferroelectric layer 122 may extend conformally along the outer side of the channel layer 132. In some embodiments, the first ferroelectric layer 122 may function as a gate dielectric in transistor operation of a cell transistor. As another example, an additional dielectric layer (not shown) may be formed between the insertion layer 120 and the channel layer 132, and the additional dielectric layer surrounds the channel layer 132. The additional dielectric layer may be formed of at least one of silicon oxide, silicon nitride and a combination thereof.

The first ferroelectric layer 122 may be formed of or include ferroelectrics. The ferroelectrics means a material which has a spontaneous polarization, wherein a direction of the polarization may be changed by an external electric field. For example, the first ferroelectric layer 122 may include or be formed of at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

In the semiconductor device according to some embodiments, the dielectric layer 121 may be not interposed between the gate electrodes 112 and 117 and the insertion layer 120, but is interposed between the mold insulating films 110 and 115 and the insertion layer 120. The gate electrodes 112 and 117 are in contact with the insertion layer 120. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The dielectric layer 121 surrounds the first ferroelectric layer 122, and may expose positions corresponding to the gate electrodes 112 and 117. For example, the dielectric layer 121 may extend conformally along the outer side of the first ferroelectric layer 122 in which the gate electrodes 112 and 117 are not disposed. The gate electrodes 112 and 117 are in contact with the first ferroelectric layer 122. The term “positions corresponding to the gate electrodes” refers to a plurality of regions disposed along a surface of the first ferroelectric layer 122 that overlaps the gate electrodes 112 and 117 in a horizontal direction. Therefore, each of the “positions corresponding to the gate electrodes” is spaced apart to adjacent ones of the “positions corresponding to the gate electrodes” in the vertical direction, and the number of the gate electrodes is equal to the number of the “positions corresponding to the gate electrodes” in the region R.

In a certain specific etching process, the dielectric layer 121 has a different etching rate from those of the mold insulating films 110 and 115. In the certain specific etching process, the dielectric layer 121 has a lower etching rate than those of the mold insulating films 110 and 115. For example, the etching rate of the dielectric layer 121 may be 1/350 to 1/500 times the etching rate of the mold insulating films 110 and 115 in the certain specific etching process. The dielectric layer 121 may be formed of or include, for example, at least one of titanium oxide, hafnium oxide, zirconium oxide, silicon oxide and aluminum oxide. For example, when all of the mold insulating films 110 and 115 and the dielectric layer 121 are formed of silicon oxide, the compositions of the mold insulating films 110 and 115 and the dielectric layer 121 may be different from each other. For example, the concentration of silicon in the mold insulating films 110 and 115 may be different from the concentration of silicon in the dielectric layer 121. The term “etching rate” refers to the removed amount of the target material (e.g., film, layer or pattern) of time per unit with respect to (i.e., during or in) an etching process.

In some embodiments, the plurality of channel structures CH may be arranged in the form of a zigzag. For example, as shown in FIG. 3, the plurality of channel structures CH may be arranged alternately in the first direction X and the second direction Y. Such channel structures CH may further improve the degree of integration of the semiconductor memory device. The number, placement, and the like of the channel structures CH are merely exemplary and are not limited to those shown. In some other embodiments, the plurality of channel structures CH may be arranged in the form of honeycomb.

The word line cutting region WC may extend in the first direction X across the first and second mold stacks MS1 and MS2. The first and second mold stacks MS1 and MS2 may be divided by the word line cutting regions WC to form the plurality of memory cell blocks (e.g., BLK1 to BLKn of FIG. 1). The plurality of word line cutting regions WC may be arranged two-dimensionally in a plane parallel to the first direction X and the second direction Y. For example, the word line cutting regions WC each extend in the first direction X, and are spaced apart from each other in the second direction Y.

The word line cutting region WC may include an insulating material, for example, at least one of silicon oxide, silicon nitride and silicon oxynitride, but is not limited thereto.

In some embodiments, the word line cutting region WC may include an insulating spacer 152 and a first substrate contact 154.

The first substrate contact 154 may be connected to the cell substrate 100. For example, the first substrate contact 154 may extend in the third direction Z, penetrate the first and second mold stacks MS1 and MS2, and be connected to the cell substrate 100. In some other embodiments, the first substrate contact 154 may not be formed.

The insulating spacer 152 may extend along the side face of the first substrate contact 154. The insulating spacer 152 may include an insulating material, for example, but is not limited to, at least one of silicon oxide, aluminum oxide, tantalum oxide, and combinations thereof. Such an insulating spacer 152 may electrically isolate the first substrate contact 154 from each of the gate electrodes 112 and 117.

The bit line BL may be formed on the first and second mold stacks MS1 and MS2. The plurality of bit lines BL may be arranged two-dimensionally in a plane parallel to the first direction X and the second direction Y. For example, the bit lines BL each extend in the second direction Y, and are spaced apart from each other in the first direction X.

The bit line BL may extend in the second direction Y and may be connected to a plurality of channel structures CH. For example, a channel pad 136 connected to the channel structure CS may be formed on the channel structure CS. Also, a bit line contact 182 connected to the channel pad 136 may be formed in the second interlayer insulating film 140b. The bit line BL may be electrically connected to the channel structures CH through the channel pad 136 and the bit line contact 182.

As described above, one end of the channel layer 132 may be connected to the cell substrate 100. The other end of the channel layer 132 may be electrically connected to the bit line BL. For example, the channel pad 136 may be connected to the upper side of the channel layer 132, as shown in FIG. 5. Accordingly, the channel layer 132 may electrically connect the common source line (e.g., CSL of FIG. 2) to the bit line BL. As an example, when the cell substrate 100 is provided as a common source line, the channel layer 132 may electrically connect the cell substrate 100 to the bit line BL.

Although the insertion layer 120 is only shown as extending along the side face of the channel pad 136, this is merely an example. As another example, the lower side of the channel pad 136 may be connected to the upper side of insertion layer 120.

Each of the gate contacts 162 may be connected to corresponding one of the gate electrodes 112 and 117. For example, the gate electrodes 112 and 117 may be stacked on the extension region EXT in a stepped manner. The plurality of gate contacts 162 each may extend in the third direction Z, penetrate the first interlayer insulating films 140a and/or the second interlayer insulating films 140b, and be connected to the corresponding gate electrodes 112 and 117 on the extension region EXT.

The cell wiring structure 180 may be formed on the first and second mold stacks MS1 and MS2. For example, the first inter-wiring insulating film 142 may be formed on the second inter layer insulating film 140b, and the cell wiring structure 180 may be formed within and/or under the first inter-wiring insulating film 142. A portion of the cell wiring structure 180 may be the bit lines BL. The cell wiring structure 180 may be electrically connected to the gate contacts 162, the bit line contact 182, the gate contact 162 and/or the first substrate contact 154. Accordingly, the cell wiring structure 180 may be electrically connected to the channel structure CS, the gate electrodes 112 and 117, and/or the cell substrate 100. The number of layers, placement, and the like of the shown cell wiring structure 180 are merely exemplary, and the embodiment is not limited thereto.

In some embodiments, a second substrate contact 164, that connects the cell substrate 100 and the cell wiring structure 180, may be formed. The second substrate contact 164 may, for example, extend in the third direction Z and penetrate the interlayer insulating films 140a and 140b, and electrically connect the cell substrate 100 to the cell wiring structure 180. In some other embodiments, the second substrate contact 164 may not be formed.

The peripheral circuit structure PERI may include a peripheral circuit substrate 200, a peripheral circuit element PT, and a peripheral circuit wiring structure 260.

The peripheral circuit substrate 200 may include a semiconductor substrate such as, for example, a silicon substrate, a germanium substrate or a silicon-germanium substrate. Alternatively, the peripheral circuit substrate 200 may include a silicon-on-insulator (SOI) substrate, a germanium-on-insulator (GOI) substrate, or the like.

The peripheral circuit element PT may be formed on the peripheral circuit substrate 200. The peripheral circuit element PT may constitute a peripheral circuit (e.g., 30 of FIG. 1) that controls the operation of the memory cell array 20. For example, the peripheral circuit element PT may include a control logic (e.g., 37 of FIG. 1), a row decoder (e.g., 33 of FIG. 1), a page buffer (e.g., 35 of FIG. 1), and the like. In the following description, a surface of the peripheral circuit substrate 200, on which the peripheral circuit elements PT are disposed may be referred to a front side of the peripheral circuit substrate 200. In contrast, a surface of the peripheral circuit substrate 200 opposite to the front side of the peripheral circuit substrate 200 may be referred to as a back side (i.e., lower side) of the peripheral circuit substrate 200.

The peripheral circuit element PT may include, for example, but is not limited to, a transistor. For example, the peripheral circuit element PT may include not only various active elements such as a transistor, but also various passive elements such as a capacitor, a resistor and an inductor.

The peripheral circuit wiring structure 260 may be formed on the peripheral circuit element PT. For example, a second inter-wiring insulating film 240 may be formed on the front side of the peripheral circuit substrate 200, and the peripheral circuit wiring structure 260 may be formed within and/or under the second inter-wiring insulating film 240. The peripheral circuit wiring structure 260 may be electrically connected to the peripheral circuit element PT. The number of layers, placement, and the like of the shown peripheral circuit wiring structure 260 are merely examples, and are not limited thereto.

In some embodiments, the cell structure CELL may be stacked on the peripheral circuit structure PERI. For example, the cell structure CELL may be stacked on the second inter-wiring insulating film 240.

In some embodiments, a through plug 166, that connects the cell wiring structure 180 to the peripheral circuit wiring structure 260, may be formed. The through plug 166 may be formed on the through region THR. The through plug 166 may extend, for example, in the third direction Z and penetrate the second interlayer insulating film 140b, the first interlayer insulating film 140a, and the insulating substrate 101. The cell wiring structure 180 may be electrically connected to the peripheral circuit wiring structure 260 through the through plug 166. Accordingly, the bit line BL, the gate electrodes 112 and 117 and/or the cell substrate 100 may be electrically connected to the peripheral circuit element PT.

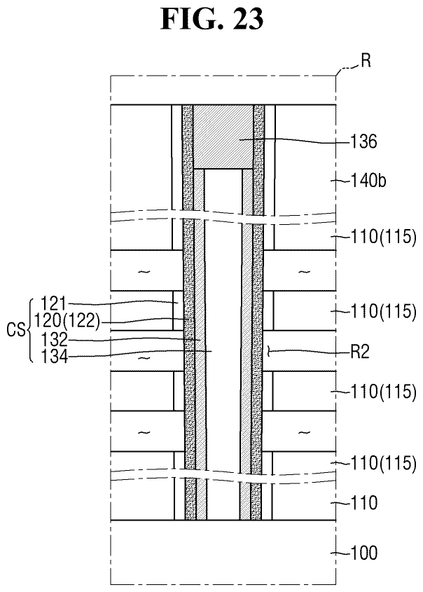

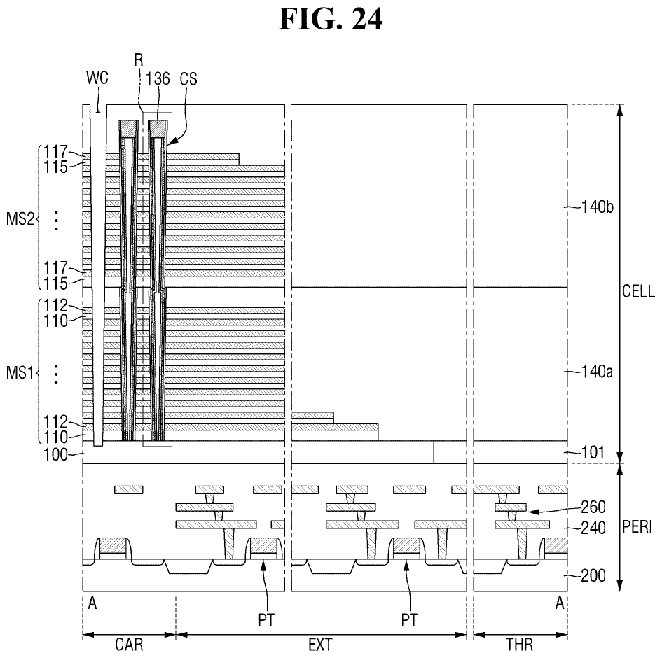

In a reference art, a dielectric layer 121 may be disposed between the gate electrodes 112 and 117 and the first ferroelectric layer 122 to increase a memory window of the semiconductor memory device. The dielectric layer 121 may function as an etching stop film in the process of removing a mold sacrificial film (111 and 116 of FIGS. 23 and 24) to form the gate electrodes 112 and 117. However, the dielectric layer 121 may cause depolarization, which may degrade retention and/or endurance of the semiconductor memory device. Therefore, retention and endurance of the semiconductor memory device may be in a trade-off relationship with the memory window of the semiconductor memory device, in the reference art.

However, in the semiconductor memory device according to some embodiments, the dielectric layer 121 is interposed between the mold insulating films 110 and 115 and the first ferroelectric layer 122, but may be not interposed between the gate electrodes 112 and 117 and the first ferroelectric layer 122. Therefore, retention and/or endurance of the semiconductor memory device may be improved.

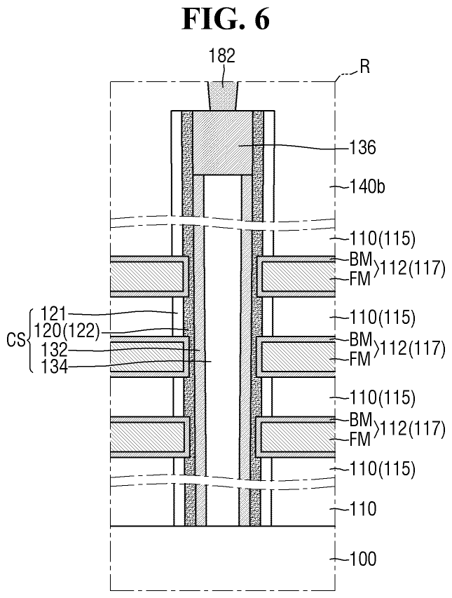

FIGS. 6 to 13 are enlarged views for explaining the region R of FIG. 4. For clarity of explanation, repeated parts of those described above using FIGS. 1 to 5 will be briefly explained or omitted.

Referring to FIGS. 4 and 6, in a semiconductor memory device according to some embodiments, a portion of each of the gate electrodes 112 and 117 extend into recesses formed in the insertion layer 120. For example, the portion of each of the gate electrodes 112 and 117 may extend into an interior of the insertion layer 120. The portion of each of the gate electrodes 112 and 117 may extend into the first ferroelectric layer 122. For example, the portion of each of the gate electrodes 112 and 117 may be disposed inside the first ferroelectric layer 122.

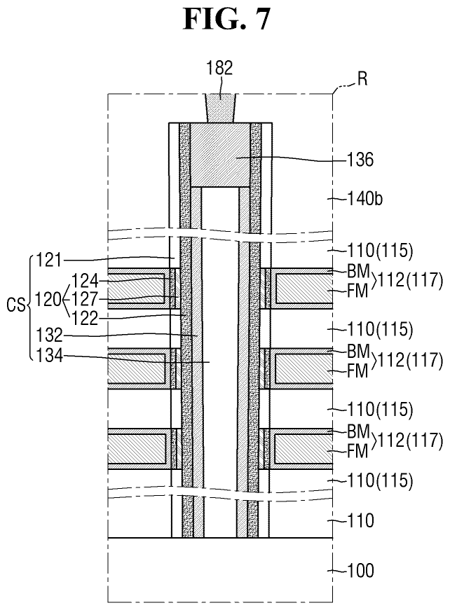

Referring to FIGS. 4 and 7, in a semiconductor memory device according to some embodiments, the insertion layer 120 includes first and second ferroelectric layers 122 and 124 and a first metal layer 127. The first ferroelectric layer 122, the first metal layer 127, and the second ferroelectric layer 124 are sequentially stacked on the side face of the channel layer 132. The first metal layer 127 is interposed between the first and second ferroelectric layers 122 and 124.

The second ferroelectric layer 124 and the first metal layer 127 are disposed at positions corresponding to the gate electrodes 112 and 117. The second ferroelectric layer 124 and the first metal layer 127 may be interposed between the gate electrodes 112 and 117 and the first ferroelectric layer 122. The first metal layer 127 may be interposed between the second ferroelectric layer 124 and the first ferroelectric layer 122. The gate electrodes 112 and 117 are in contact with the second ferroelectric layer 124.

For example, the second ferroelectric layer 124 may include or be formed of at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

The dielectric layer 121 may expose positions corresponding to the gate electrodes 112 and 117. For example, the dielectric layer 121 may not be disposed at positions corresponding to the gate electrodes 112 and 117. The second ferroelectric layer 124 and the first metal layer 127 may be disposed at positions corresponding to the gate electrodes 112 and 117 exposed by the dielectric layer 121. Each separated portion of the second ferroelectric layer 124 may be spaced apart from adjacent separated portions of the second ferroelectric layer 124 in the vertical direction by the dielectric layer 121. Each separated portion of the first metal layer 127 may be spaced apart from adjacent separated portions of the first metal layer 127 in the vertical direction by the dielectric layer 121.

The first metal layer 127 may serve as a floating gate, and the first ferroelectric layer 122 may function as a gate dielectric. The first metal layer 127 may be electrically insulated from the channel pad 136 and an uppermost one of the second gate electrodes 117 by the first ferroelectric layer 122. The uppermost one of the second gate electrodes 117 may serve as the string selection line (SSL of FIG. 2). The length of the first metal layer 127 in the third direction Z may be, for example, 1 to 30 nm. A distance between the uppermost one and the adjacent one of the first metal layers 127 in the third direction Z may be, for example, 1 to 30 nm.

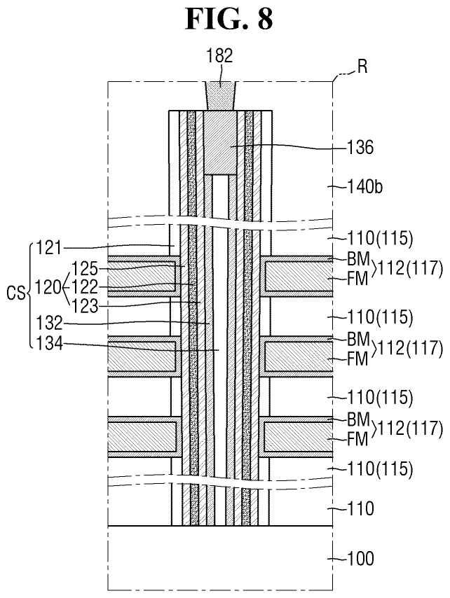

Referring to FIGS. 4 and 8, in a semiconductor memory device according to some embodiments, the insertion layer 120 includes a first ferroelectric layer 122 and first and second antiferroelectric layers 123 and 125. The insertion layer 120 has a super lattice structure in which first and second antiferroelectric layers 123 and 125 and the first ferroelectric layer 122 are alternately stacked on the side face of the channel layer 132. The gate electrodes 112 and 117 are in contact with the outermost layer of the insertion layer 120.

For example, the insertion layer 120 may include a first antiferroelectric layer 123, a first ferroelectric layer 122 and a second antiferroelectric layer 125 that are sequentially stacked on the side face of the channel layer 132.

The first antiferroelectric layer 123, the first ferroelectric layer 122 and the second antiferroelectric layer 125 may extend in the vertical direction Z. The first antiferroelectric layer 123, the first ferroelectric layer 122 and the second antiferroelectric layer 125 may extend along the side faces of the channel layer 132. The first antiferroelectric layer 123 may be interposed between the first ferroelectric layer 122 and the channel layer 132. The second antiferroelectric layer 125 may be interposed between the dielectric layer 121 and the first ferroelectric layer 122, and between the gate electrodes 112 and 117 and the first ferroelectric layer 122. The gate electrodes 112 and 117 are in contact with the second antiferroelectric layer 125.

The dielectric layer 121 may be not interposed between the gate electrodes 112 and 117 and the second antiferroelectric layer 125, but may be interposed between the mold insulating films 110 and 115 and the second antiferroelectric layer 125.

The first antiferroelectric layer 123 and the second antiferroelectric layer 125 may each include or be formed of antiferroelectrics. The antiferroelectrics refer to a material that does not have spontaneous polarization in a state in which no external electric field is applied, but has a direction of polarization that changes like ferroelectrics when an external electric field is applied. For example, the first antiferroelectric layer 123 and the second antiferroelectric layer 125 may each include, but not limited to, PbZrO3 or the like.

Since the semiconductor memory device according to some embodiments includes the insertion layer 120 having a super lattice structure, the memory window of the semiconductor memory device can be improved or increased.

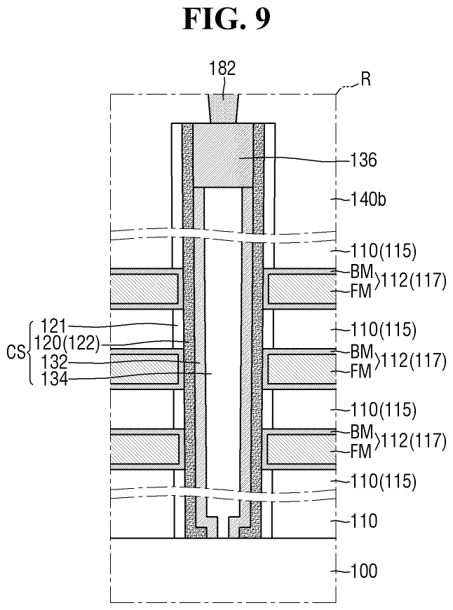

Referring to FIGS. 4 and 9, in a semiconductor memory device according to some embodiments, a part of the insertion layer 120 extends along the upper side of the cell substrate 100.

For example, a part of the first ferroelectric layer 122 may extend along a portion of the upper side of the cell substrate 100. The lower part of the first ferroelectric layer 122 may have an “L” shape. The channel layer 132 penetrates the first ferroelectric layer 122, and may be connected to the cell substrate 100. For example, the channel layer 132 may extend conformally along the profile of the first ferroelectric layer 122 and a portion of the upper side of the cell substrate 100 exposed from by the first ferroelectric layer 122. For example, the first ferroelectric layer 122 may not be formed on a portion of the upper side of the cell substrate 100. Therefore, the channel layer 132 may contact the cell substrate 100.

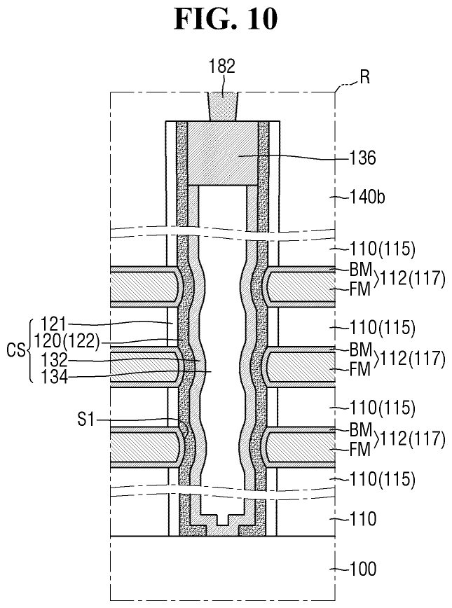

Referring to FIGS. 4 and 10, in a semiconductor memory device according to some embodiments, the gate electrodes 112 and 117 protrude toward the channel structure CS beyond the mold insulating films 110 and 115.

For example, each of the gate electrodes 112 and 117 may include a first side face S1 protruding beyond the mold insulating films 110 and 115. For example, the first side face S1 may be convex toward the channel structure CS. The first ferroelectric layer 122, the channel layer 132 and the core insulating layer 134 may be sequentially stacked on the side faces of the mold insulating films 110 and 115 and the gate electrodes 112 and 117. A part of the first ferroelectric layer 122 may extend conformally along the profile of the first side face S1. In such a case, a contact area between each of the gate electrodes 112 and 117 and the first ferroelectric layer 122 is increased, and a charge tunneling phenomenon caused by the first ferroelectric layer 122 at the time of the write operation may be reduced.

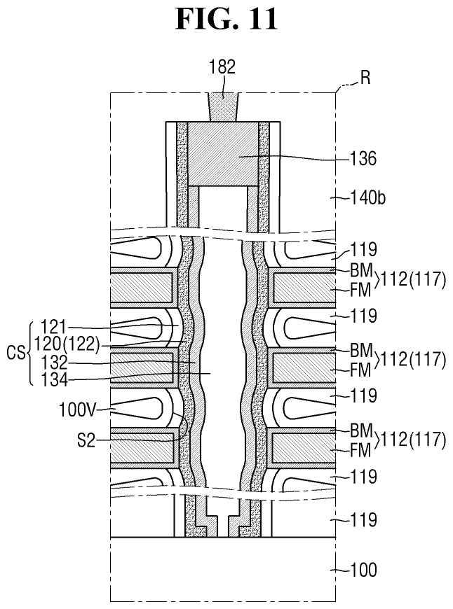

Referring to FIGS. 4 and 11, in a semiconductor memory device according to some embodiments, a void 100V is interposed between the gate electrodes 112 and 117 is included.

The gate electrodes 112 and 117 may be sequentially stacked on the cell substrate 100 in the vertical direction, and the void 100V may be intervening between the gate electrodes 112 and 117. The void 100V may be, for example, an air gap. The term “air” as discussed herein, may refer to atmospheric air, or other gases that may be present during the manufacturing process. It should be appreciated that an “air gap” may comprise a gap having air or other gases (e.g., such as those present during manufacturing) or may comprise a gap forming a vacuum therein. For example, the mold insulating films 110 and 115 may be removed, and a sealing insulating film 119 with poor step coverage may be deposited in the region from which the mold insulating films 110 and 115 are removed. Therefore, the void 100V may be provided within the sealing insulating film 119. Hereinafter, the sealing insulating film 119 may also be referred to as a mold insulating film. Therefore, the mold insulating film may include the void 100V. Accordingly, it is possible to enhance the performance of the semiconductor memory device by reducing the disturbance between the memory cells. As used herein, the term “step coverage” is used to refer to the ratio of the minimum thickness of a material going over a horizontal to vertical transition to the thickness of the same material on a flat surface. For example, the term “step coverage” is used to refer to a ratio of a thickness of a material over a step edge to the thickness of the material on a flat surface.

In the semiconductor memory device according to some embodiments, the scaling insulating film 119 may include a second side face S2 that protrudes beyond the gate electrodes 112 and 117, though not shown in the drawing. For example, the second side face S2 may be convex toward the channel structure CS. The dielectric layer 121, the insertion layer 120, the channel layer 132 and the core insulating layer 134 may be sequentially stacked on the side face of the sealing insulating film 119. The insertion layer 120, the channel layer 132 and the core insulating layer 134 may be sequentially stacked on the side faces of the gate electrodes 112 and 117. A part of the insertion layer 120 may extend conformally along the profile of the second side S2.

Referring to FIGS. 4, 12 and 13, in a semiconductor memory device according to some embodiments, the insertion layer 120 includes first and second ferroelectric layers 122 and 124 and a first antiferroelectric layer 123. The first and second ferroelectric layers 122 and 124 and the first antiferroelectric layer 123 are alternately stacked on the side faces of the channel layer 132, and have a super lattice structure. The gate electrodes 112 and 117 are in contact with the outermost layer of the insertion layer 120.

For example, the insertion layer 120 may include a first ferroelectric layer 122, a first antiferroelectric layer 123 and a second ferroelectric layer 124, which are sequentially stacked on the side face of the channel layer 132.

The first antiferroelectric layer 123 may extend in the vertical direction Z. The first antiferroelectric layer 123 and the first ferroelectric layer 122 may extend along the side face of the channel layer 132. The second ferroelectric layer 124 may be disposed at a position corresponding to the gate electrodes 112 and 117. The second ferroelectric layer 124 may be interposed between the gate electrodes 112 and 117 and the first antiferroelectric layer 123. The gate electrodes 112 and 117 are in contact with the second ferroelectric layer 124. The first antiferroelectric layer 123 may be interposed between the first ferroelectric layer 122 and the dielectric layer 121, and between the first ferroelectric layer 122 and the second ferroelectric layer 124.

For example, the first antiferroelectric layer 123 may include a vertical part that extends long in the third direction Z, and a horizontal part that extends from the vertical part toward the second ferroelectric layer 124. The horizontal part and the second ferroelectric layer 124 may be disposed at positions corresponding to the gate electrodes 112 and 117. As yet another example, the first antiferroelectric layer 123 may include only the vertical part extending long in the third direction Z.

For example, the second ferroelectric layer 124 may include or be formed of at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide and combinations thereof.

For example, the first antiferroelectric layer 123 may include, but is not limited to, PbZrO3 or the like.

The dielectric layer 121 may not be interposed between the gate electrodes 112 and 117 and the second ferroelectric layers 124, but may be interposed between the mold insulating films 110 and 115 and the first antiferroelectric layer 123. The second ferroelectric layers 124 each may be separated by the dielectric layer 121 in the vertical direction from an adjacent one of the second ferroelectric layers 124.

In the semiconductor memory device according to some embodiments, the channel layer 132 includes an n-type channel layer 130 and a p-type channel layer 131.

The n-type channel layer 130 and the p-type channel layer 131 each extend in the third direction Z, and may intersect the plurality of gate electrodes 112 and 117. Further, one end of the n-type channel layer 130 and one end of the p-type channel layer 131 may be electrically connected to a common source line (e.g., CSL of FIG. 2), respectively. For example, the n-type channel layer 130 may include n-type impurities, and the p-type channel layer 131 may include p-type impurities. The n-type channel layer 130 may include an oxide semiconductor material, like for example, indium gallium zinc oxide (InxGayZnzO, commonly referred to as “IGZO”), indium tungsten oxide (InxWyO, commonly referred to as “IWO”), and other similar materials. The p-type channel layer 131 may include an oxide semiconductor material, like for example, copper oxide (CuO) and other similar materials.

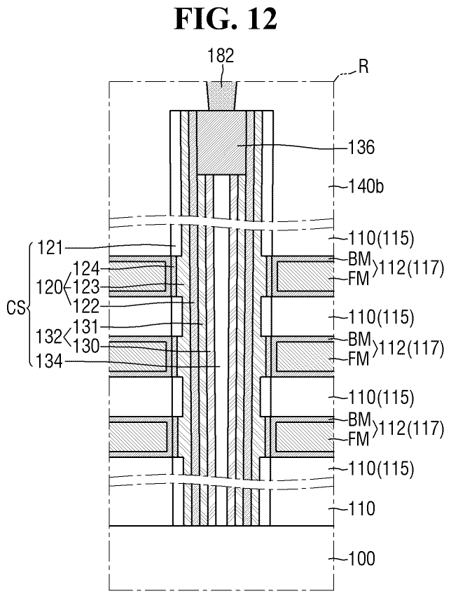

Referring to FIG. 12, in the semiconductor memory device according to some embodiments, an n-type channel layer 130 may be interposed between the p-type channel layer 131 and the core insulating layer 134.

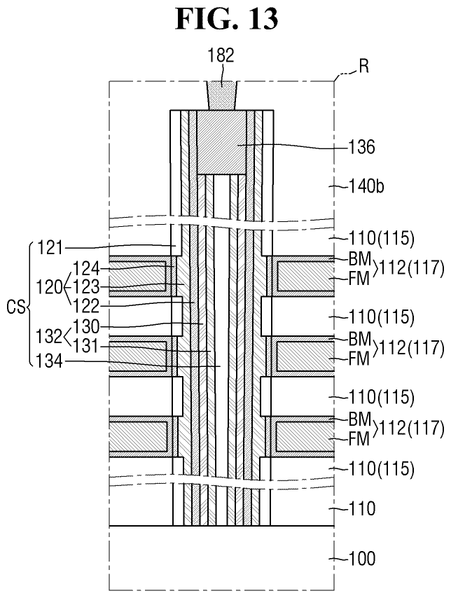

Referring to FIG. 13, in the semiconductor memory device according to some embodiments, a p-type channel layer 131 may be interposed between the n-type channel layer 130 and the core insulating layer 134.

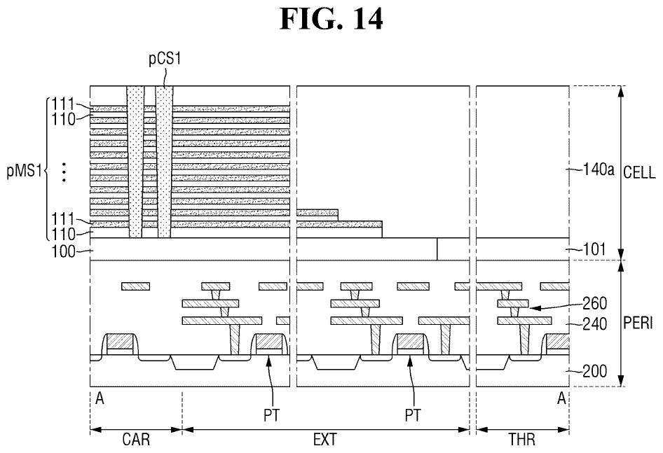

FIGS. 14 to 26 are cross-sectional views illustrating a method for fabricating a semiconductor memory device according to some embodiments. For convenience of explanation, repeated parts of those described above using FIGS. 1 to 13 will be briefly explained or omitted.

Referring to FIG. 14, a first preliminary mold pMS1 and a first preliminary channel pCS1 are formed on the cell substrate 100.

The first preliminary mold pMS1 may be formed on the front side of the cell substrate 100. The first preliminary mold pMS1 may include a plurality of first mold insulating films 110 and a plurality of first mold sacrificial films 111 that are alternately stacked on the cell substrate 100. The first mold sacrificial films 111 may include a material having an etching selectivity with respect to the first mold insulating films 110. As an example, the first mold insulating films 110 may include a silicon oxide film, and the first mold sacrificial film 111 may include a silicon nitride film. The term “etching selectivity” as used herein refers to the ratio of the etching rates of two different materials with respect to a certain specific etching process. When “a material A has an etching selectivity with respect to a material B,” it should be appreciated that a certain specific etching process removes a significant amount of the material B while providing little or no removal of the material A or vice versa.

The first preliminary mold pMS1 on the extension region EXT may be patterned stepwise. As a result, the first preliminary mold pMS1 may be stacked stepwise.

The first preliminary channel pCS1 may penetrate the first preliminary mold pMS1 on the cell array region CA. Also, the first preliminary channel pCS1 may be connected to the cell substrate 100. For example, a first interlayer insulating film 140a that covers the first preliminary mold pMS1 may be formed on the cell substrate 100. The first preliminary channel pCS1 may penetrate the first interlayer insulating film 140a, and the first preliminary channel pCS1 may be connected to the cell substrate 100.

The first preliminary channel pCS1 may include a material having an etching selectivity with respect to the first mold insulating films 110 and the first mold sacrificial films 111. As an example, the first preliminary channel pCS1 may include polysilicon (poly Si).

In some embodiments, the cell substrate 100 may be stacked on the peripheral circuit structure PERI. For example, the cell substrate 100 may be stacked on the second inter-wiring insulating film 240.

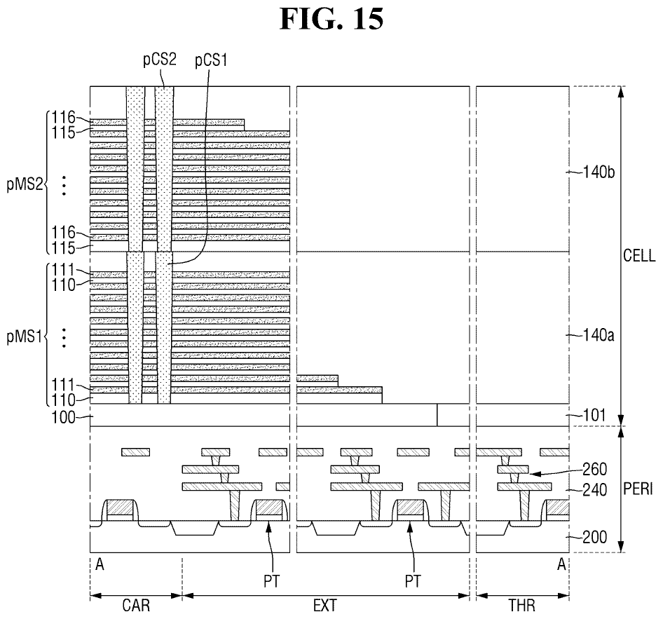

Referring to FIG. 15, a second preliminary mold pMS2 and a second preliminary channel pCS2 are formed on the first preliminary mold pMS1.

The second preliminary mold pMS2 may include a plurality of second mold insulating films 115 and a plurality of second mold sacrificial films 116 that are alternately stacked on the first preliminary mold pMS1. Since formation of the second preliminary mold pMS2 may be similar to formation of the first preliminary mold pMS1, a detailed description thereof will not be provided in detail.

The second preliminary channel pCS2 may penetrate the second preliminary mold pMS2 on the cell array region CA. Also, the second preliminary channel pCS2 may be connected to the first preliminary channel pCS1. Since the method for forming the second preliminary channel pCS2 may be similar to the method for forming the first preliminary channel pCS1, a detailed description thereof will not be provided in detail.

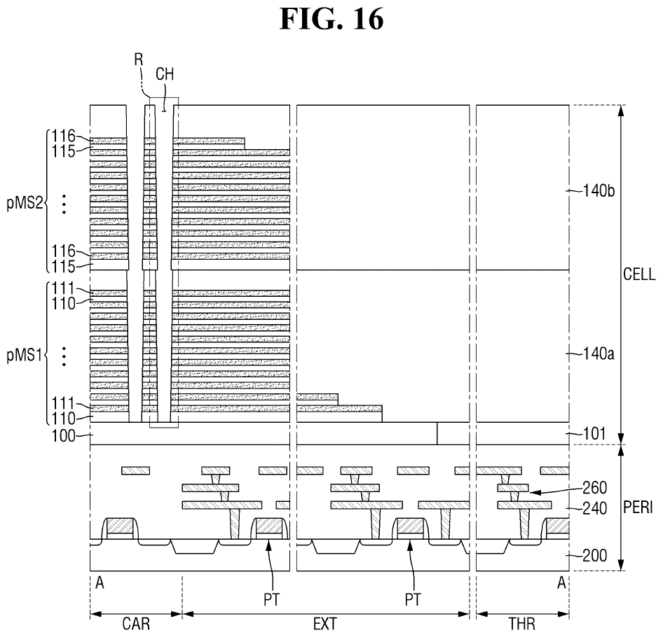

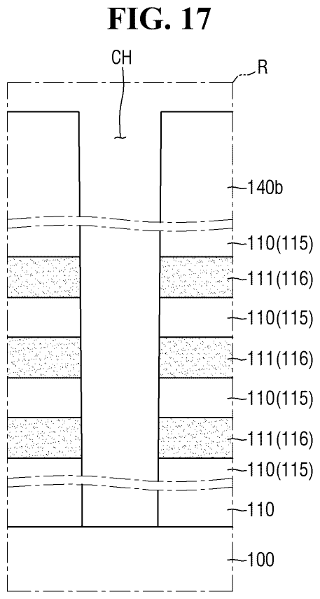

Referring to FIGS. 16 and 17, the first preliminary channel pCS1 and the second preliminary channel pCS2 are removed. For reference, FIG. 17 is an enlarged view of a region R of FIG. 9.

Since the first preliminary channel pCS1 and the second preliminary channel pCS2 may each include a material that has etching selectivity with respect to the first mold insulating films 110 and the first mold sacrificial films 111, they may be selectively removed. As the first preliminary channel pCS1 and the second preliminary channel pCS2 are removed, a channel hole CH extending in the third direction Z and penetrating the first preliminary mold pMS1 and the second preliminary mold pMS2 may be formed.

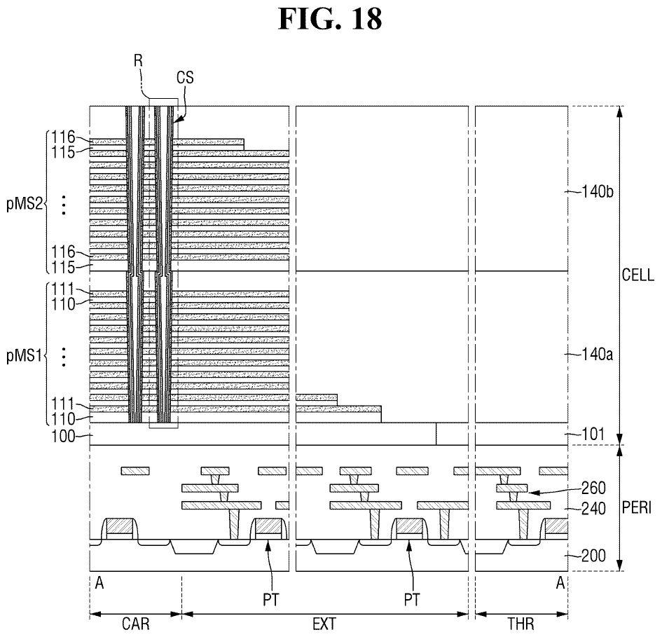

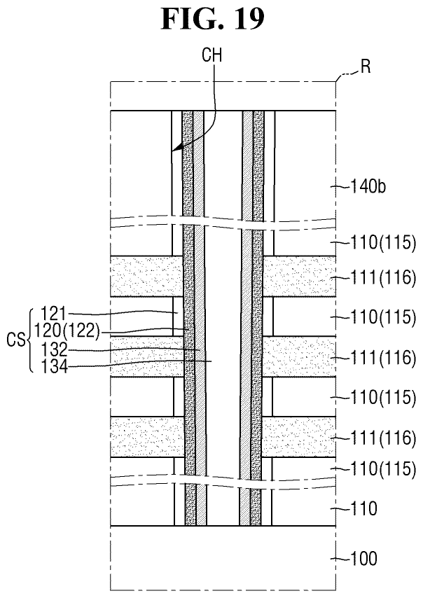

Referring to FIGS. 18 and 19, a channel structure CS is formed. For reference, FIG. 19 is an enlarged view of a region R of FIG. 18.

The dielectric layer 121 may be formed in the channel hole CH. The dielectric layer 121 may be formed, for example, by an atomic layer deposition (ALD) process. The dielectric layer 121 may include a material having an etching selectivity with respect to the mold insulating films 110 and 115 and the first and second mold sacrificial films (also collectively described as mold sacrificial films) 111 and 116.

The first ferroelectric layer 122 may be formed on the dielectric layer 121. Accordingly, the insertion layer 120 including the first ferroelectric layer 122 may be formed. The channel layer 132 may be formed on the first ferroelectric layer 122. The core insulating layer 134, which fills the region of the channel hole CH that remains after filling the dielectric layer 121, the first ferroelectric layer 122 and the channel layer 132, may be formed.

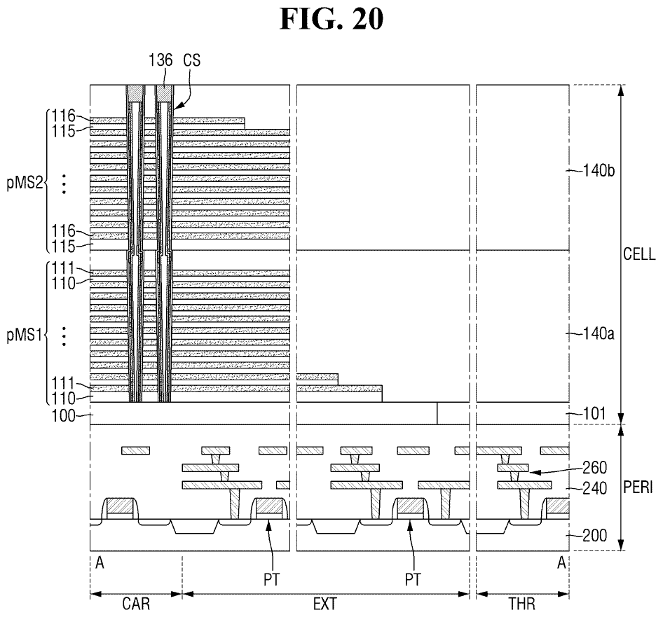

Referring to FIG. 20, a channel pad 136 is formed on the channel structure CS. The channel pad 136 may be connected to the channel structure CS. For example, the channel pad 136 may be connected to the upper side of the channel layer (132 of FIG. 19).

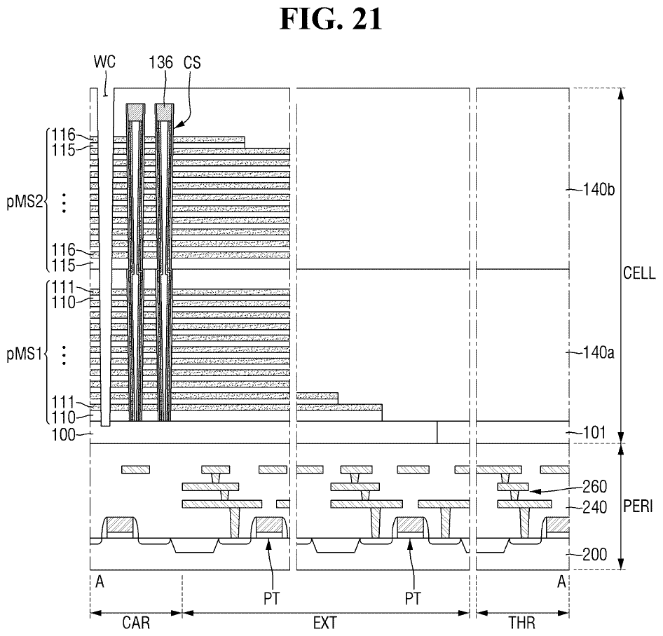

Referring to FIG. 21, a word line cutting region WC is formed.

The word line cutting region WC may extend in the first direction (for example, X of FIG. 3) across the first preliminary mold pMS1 and the second preliminary mold pMS2.

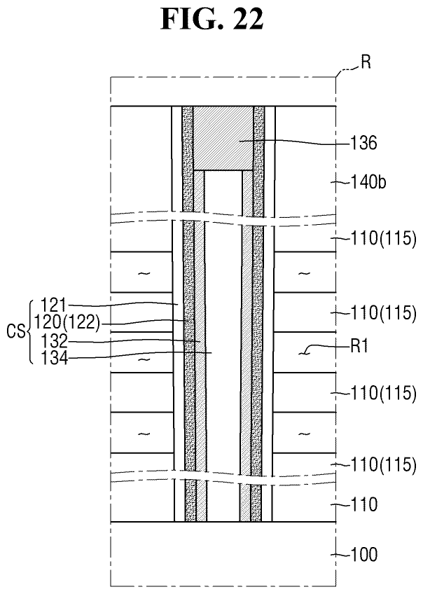

Referring to FIGS. 22 and 23, the mold sacrificial films 111 and 116 exposed by the word line cutting region WC are selectively removed to form the first recess R1.

The first recess R1 may expose a part of the dielectric layer 121. Since the dielectric layer 121 includes a material having an etching selectivity with respect to the mold sacrificial films 111 and 116, when the mold sacrificial films 111 and 116 are removed, the dielectric layer 121 may remain without being removed (or with little amount thereof being removed). Therefore, the dielectric layer 121 may function as an etching stop film in the process of removing the mold sacrificial films 111 and 116.

Referring to FIGS. 22 and 23, the dielectric layer 121 exposed by the first recess R1 is removed to form the second recess R2. The second recess R2 may expose a part of the first ferroelectric layer 122.

The dielectric layer 121 may be etched by an atomic layer etching (ALE) process. For example, the atomic layer etching process may be a process that selectively removes a modified layer which is formed by chemically altering the surface to be etched. Since the dielectric layer 121 includes a material having an etching selectivity with respect to the mold insulating films 110 and 115, when the dielectric layer 121 is removed, the mold insulating films 110 and 115 may remain without being removed (or with little amount thereof being removed).

For example, a part of the first ferroelectric layer 122 may be etched in the process of removing the dielectric layer 121. In this case, the semiconductor memory device described above using FIG. 6 may be fabricated by further performing the processes described below using FIGS. 23 to 26.

Referring to FIGS. 23, 24 and 5, a plurality of first and second gate electrodes (also, collectively described as gate electrodes) 112 and 117 are formed in the second recess R2. For example, gate electrodes 112 and 117, that replace the region in which the mold sacrificial films 111 and 116 and the dielectric layer 121 are removed, may be formed. Accordingly, the first mold stack MS1 including the plurality of first gate electrodes 112 and the second mold stack MS2 including the plurality of second gate electrodes 117 may be formed.

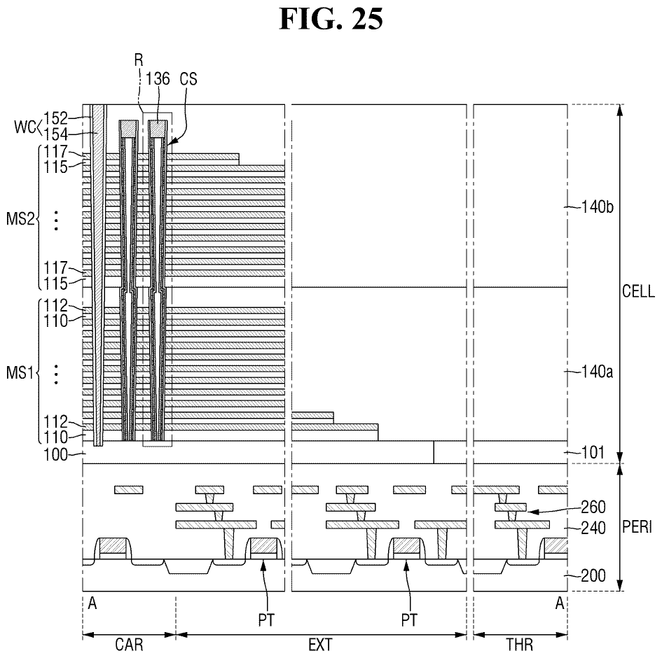

Referring to FIG. 25, an insulating spacer 152 and a first substrate contact 154 are formed.

For example, an insulating film, that fills the word line cutting region WC, may be formed and be subject to an etch-back process to form the insulating spacer 152. The first substrate contact 154 that penetrates the insulating film and is connected to the cell substrate 100 may be formed. In some other embodiments, the first substrate contact 154 may not be formed.

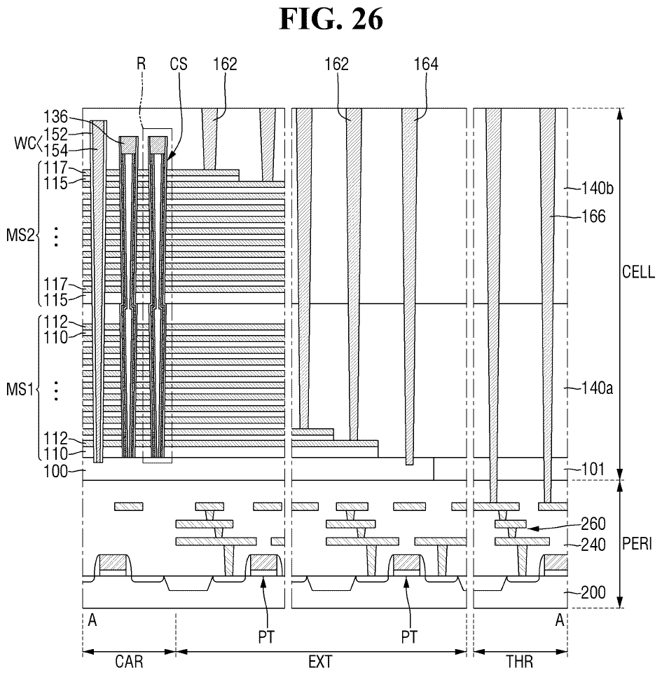

Referring to FIG. 26, a gate contact 162, the second substrate contact 164, and the through plug 166 are formed through the first mold stacks MS1 and/or the second mold stack MS2.

The plurality of gate contacts 162 may be connected to the plurality of gate electrodes 112 and 117. The second substrate contact 164 may be connected to the cell substrate 100. The through plug 166 may be connected to the peripheral circuit wiring structure 260.

Next, referring to FIG. 4, the bit line contact 182, the bit line BL and the cell wiring structure 180 are formed. Accordingly, the semiconductor memory device described above using FIGS. 3 to 5 may be fabricated.

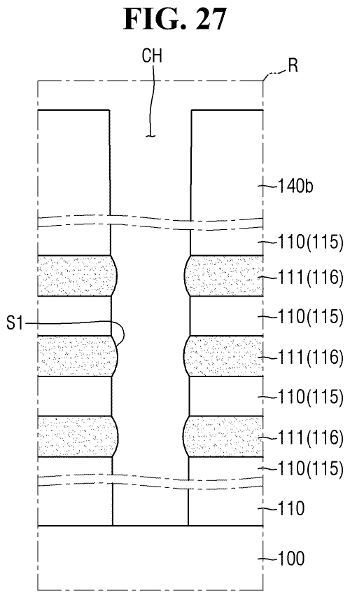

FIG. 27 is a cross-sectional view illustrating a method for fabricating a semiconductor memory device according to some embodiments. For convenience of explanation, repeated parts of those described above using FIGS. 1 to 26 will be briefly explained or omitted. FIG. 27 is a cross-sectional view illustrating process steps after FIG. 17.

Referring to FIG. 27, a recess process is performed on the mold insulating films 110 and 115. As the recess process is performed, the mold sacrificial films 111 and 116 may protrude toward the channel hole CH beyond the mold insulating films 110 and 115.

For example, the mold sacrificial films 111 and 116 may include a first side face S1 that protrudes beyond the mold insulating films 110 and 115. The first side face S1 may be convex toward the channel hole CH.

The steps described above using FIGS. 18 to 26 and FIG. 4 may then be performed. Accordingly, the semiconductor memory device described above using FIGS. 4 and 10 may be fabricated.

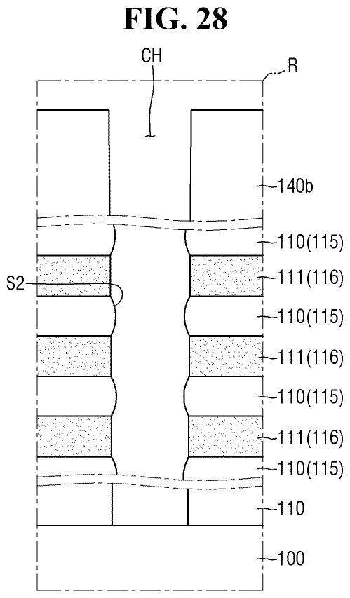

FIGS. 28 to 31 are cross-sectional views illustrating a method for fabricating a semiconductor memory device according to some embodiments. For convenience of explanation, repeated parts of those described above using FIGS. 1 to 26 will be briefly explained or omitted. FIG. 28 is a cross-sectional view illustrating process steps after FIG. 17.

Referring to FIG. 28, a recess process is performed on the mold sacrificial films 111 and 116. As the recess process is performed, the mold insulating films 110 and 115 may protrude beyond the mold sacrificial films 111 and 116 toward the channel hole CH.

For example, the mold insulating films 110 and 115 may include a second side face S2 that protrudes beyond the mold sacrificial films 111 and 116. The second side face S2 may be convex toward the channel hole CH.

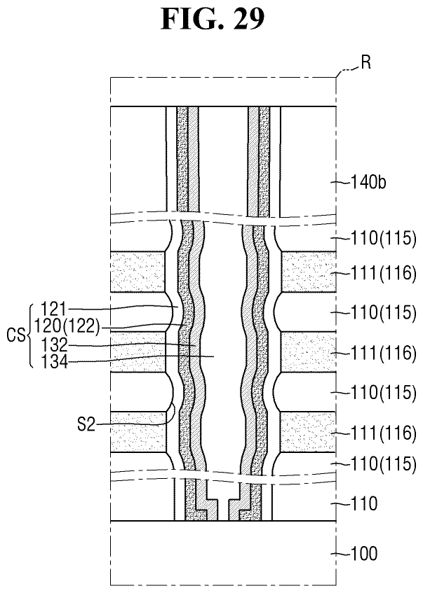

Referring to FIG. 29, a channel structure CS is formed. Since the method for fabricating the channel structure CS is the same as that described above using FIGS. 18 and 19, detailed description will not be provided.

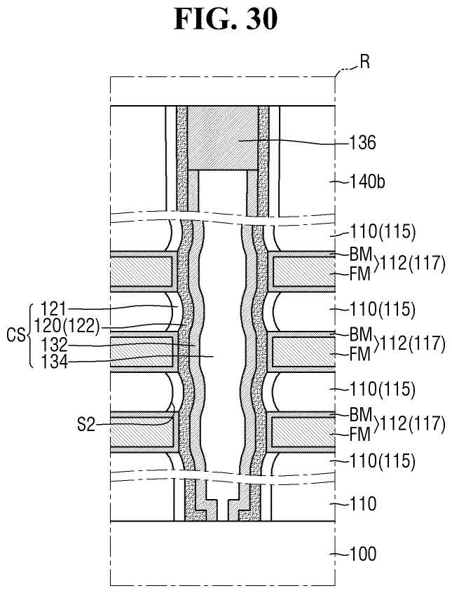

Referring to FIG. 30, gate electrodes 112 and 117 are formed. Since the method for fabricating the gate electrodes 112 and 117 is the same as that described above using FIGS. 20 to 24, the detailed description will not be provided.

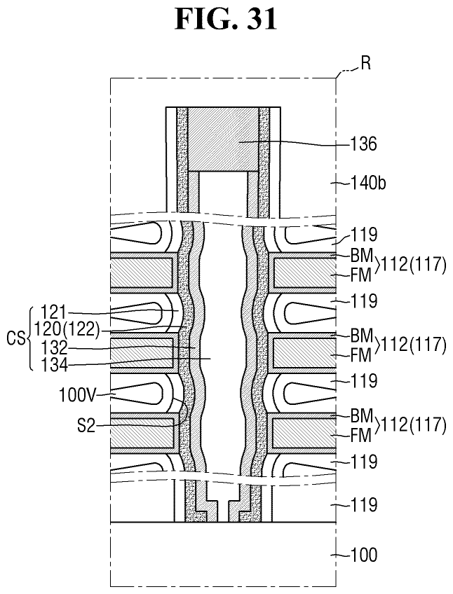

Referring to FIG. 31, a void 100V is formed.

The void 100V may be interposed between the gate electrodes 112 and 117. For example, the mold insulating films 110 and 115 may be removed, and a sealing insulating film 119 with poor step coverage may be deposited in the region from which the mold insulating films 110 and 115 are removed. Accordingly, the void 100V may be provided within the sealing insulating film 119. The process steps described above using FIGS. 25, 26 and 4 may then be performed. Accordingly, the semiconductor memory device described above using FIGS. 4 and 11 may be fabricated.

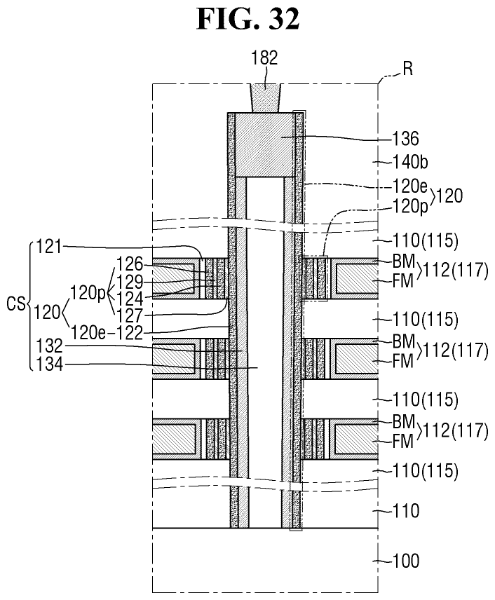

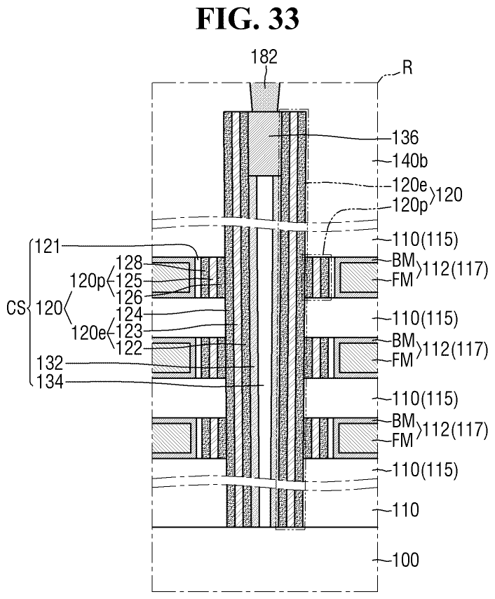

FIGS. 32 and 33 are enlarged views for explaining the region R of FIG. 4. For convenience of explanation, repeated parts of those described above using FIGS. 1 to 5 will be briefly explained or omitted.

Referring to FIGS. 4, 32 and 33, in a semiconductor memory device according to some embodiments, the insertion layer 120 includes an extension part 120e extending along the side face of the channel layer 132, and protrusion parts 120p that protrude from the extension part 120e toward the gate electrodes 112 and 117. The extension part 120e and the protrusion part 120p each include or be formed of ferroelectrics (i.e., ferroelectric material).

In the semiconductor memory devices according to some embodiments, a plurality of dielectric layers 121 may be interposed between the gate electrodes 112 and 117 and the insertion layer 120, but may be not interposed between the mold insulating films 110 and 115 and the insertion layer 120. The dielectric layers 121 each may be in contact with one of the gate electrodes 112 and 117. Each of the protrusion parts 120p may be separated from an adjacent one of the protrusion parts 120p in the third direction Z by the mold insulating films 110 and 115. For example, the dielectric layer 121 may be interposed between the protrusion parts 120p and the gate electrodes 112 and 117, and the dielectric layer 121 may be disposed at positions corresponding to the gate electrodes 112 and 117.

The dielectric layer 121 may include or be formed of, for example, but not limited to, at least one of silicon oxide, silicon nitride and silicon oxynitride. As an example, the dielectric layer 121 may include a silicon oxide film.

Referring to FIGS. 4 and 32, in a semiconductor memory device according to some embodiments, the insertion layer 120 includes first, second and third ferroelectric layers 122, 124 and 126 and first and second metal layers 127 and 129. The insertion layer 120 has a super lattice structure in which the first, second and third ferroelectric layers 122, 124 and 126 and first and second metal layers 127 and 129 are alternately stacked on the side faces of the channel layer 132. The extension part 120e may be made up of a first ferroelectric layer 122. The protrusion part 120p may be made up of the second and third ferroelectric layers 124 and 126, and the first and second metal layers 127 and 129. The protrusion part 120p may have a super lattice structure.

For example, the insertion layer 120 includes the first ferroelectric layer 122, the first metal layer 127, the second ferroelectric layer 124, the second metal layer 129 and the third ferroelectric layer 126 that are stacked sequentially on the side face of the channel layer 132.

The first metal layer 127, the second ferroelectric layer 124, the second metal layer 129 and the third ferroelectric layer 126 may be disposed at positions corresponding to the gate electrodes 112 and 117. The first metal layer 127, the second ferroelectric layer 124, the second metal layer 129 and the third ferroelectric layer 126 may be disposed between the gate electrodes 112 and 117 and the first ferroelectric layer 122.

For example, the first ferroelectric layer 122 may include only a vertical part extending long in the third direction Z. The first ferroelectric layer 122 may constitute an extension part 120c, and the first metal layer 127, the second ferroelectric layer 124, the second metal layer 129 and the third ferroelectric layer 126 may constitute a protrusion part 120p.

As yet another example, the first ferroelectric layer 122 may include a vertical part extending long in the third direction Z, and a horizontal part extending from the vertical part toward the first metal layer 127. The horizontal part may be disposed at positions corresponding to the gate electrodes 112 and 117. The vertical part of the first ferroelectric layer 122 constitutes the extension part 120c, and the horizontal part of the first ferroelectric layer 122, the first metal layer 127, the second ferroelectric layer 124, the second metal layer 129 and the third ferroelectric layer 126 may form the protrusion part 120p.

For example, each of the second and third ferroelectric layers 124 and 126 may include or be formed of at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

Referring to FIGS. 4 and 33, in a semiconductor memory device according to some embodiments, the insertion layer 120 includes first to fourth ferroelectric layers 122, 124, 126 and 128, and the first and second antiferroelectric layers 123 and 125. The extension part 120c and the protrusion part 120p as a whole may be made up of the first to fourth ferroelectric layers 122, 124, 126 and 128 and, the first and second antiferroelectric layers 123 and 125. The first to fourth ferroelectric layers 122, 124, 126 and 128 and, the first and second antiferroelectric layers 123 and 125 may have a super lattice structure.

For example, the extension part 120e of the insertion layer 120 may include the first ferroelectric layer 122, the first antiferroelectric layer 123 and the second ferroelectric layer 124 which are stacked sequentially on the side face of the channel layer 132. The protrusion part 120p of the insertion layer 120 may include the third ferroelectric layer 126, the second antiferroelectric layer 125 and the fourth ferroelectric layer 128, which are stacked sequentially on the side face of the channel layer 132. The third ferroelectric layer 126, the second antiferroelectric layer 125 and the fourth ferroelectric layer 128 may be disposed at positions corresponding to the gate electrodes 112 and 117. The third ferroelectric layer 126, the second antiferroelectric layer 125 and the fourth ferroelectric layer 128 may be disposed between the gate electrodes 112 and 117 and the first ferroelectric layer 122.

For example, each of the second to fourth ferroelectric layers 124, 126 and 128 may include or be formed of at least one of hafnium oxide, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, and combinations thereof.

For example, the first and second antiferroelectric layers 123 and 125 may each include, but not limited to, PbZrO3 or the like.

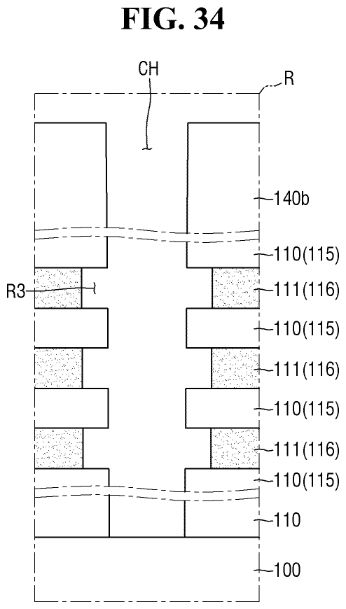

FIGS. 34 to 38 are cross-sectional views illustrating a method for fabricating a semiconductor memory device according to some embodiments. For convenience of explanation, repeated parts of those described above using FIGS. 1 to 33 will be briefly explained or omitted. FIG. 34 is a cross-sectional view illustrating process steps after FIG. 17.

Referring to FIG. 34, a recess process is performed on the mold sacrificial films 111 and 116. As the recess process is performed, the mold sacrificial films 111 and 116 including the third recess R3 may be formed.

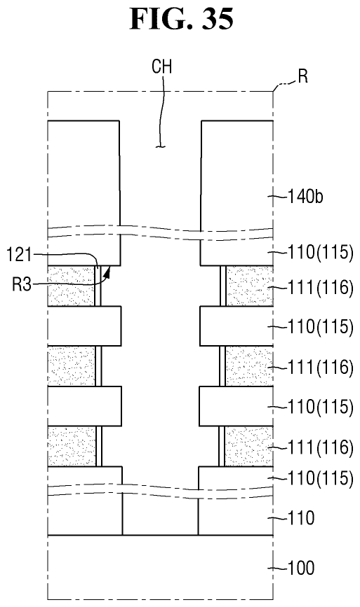

Referring to FIG. 35, a dielectric layer 121 is formed on the mold sacrificial films 111 and 116 exposed by the third recess R3.

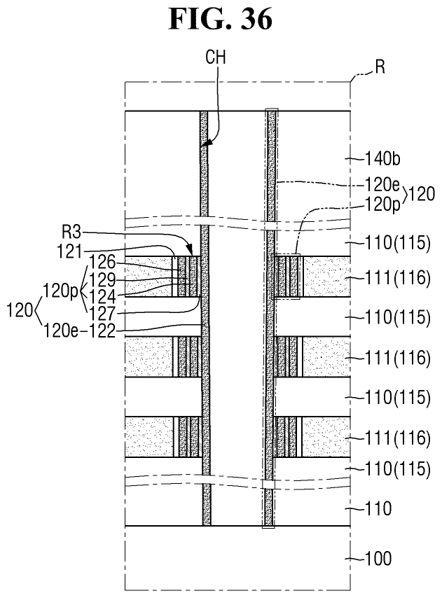

Referring to FIG. 36, an insertion layer 120 that includes the protrusion part 120p and the extension part 120e is formed.

The first ferroelectric layer 122, the first metal layer 127, the second ferroelectric layer 124 and the second metal layer 129 may be formed sequentially on the dielectric layer 121 to fill the third recess R3. Accordingly, the protrusion part 120p may be formed. The third ferroelectric layer 126 that extends along the channel layer 132 may then be formed. Accordingly, the extension part 120e may be formed.

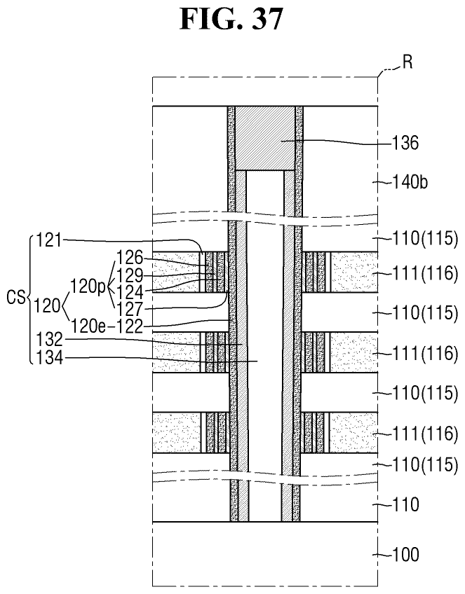

Referring to FIG. 37, a channel layer 132 may be formed on the first ferroelectric layer 122. The core insulating layer 134, which fills the region of the channel hole CH that remains after forming the dielectric layer 121, the first ferroelectric layer 122 and the channel layer 132, may be formed. The channel pad 136 may be formed on the channel structure CS. Accordingly, the channel structure CS may be formed.

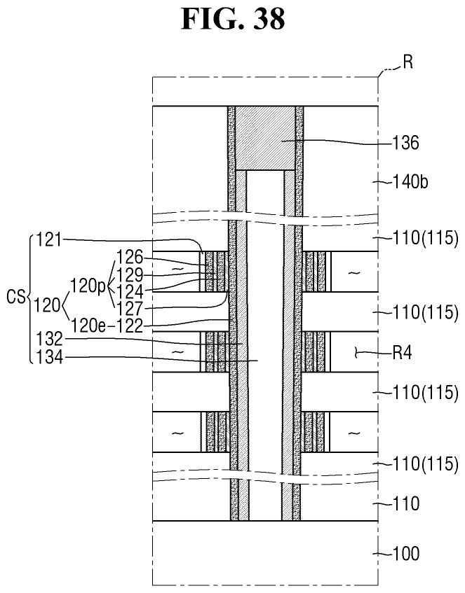

Next, the word line cutting region WC explained above using FIG. 21 is formed. Next, referring to FIG. 38, the mold sacrificial films 111 and 116 exposed by the word line cutting region (WC of FIG. 21) are selectively removed to form a fourth recess R4.

The fourth recess R4 may expose the dielectric layer 121. The dielectric layer 121 may function as an etching stop film in the process of removing the mold sacrificial films 111 and 116.

The process steps described above using FIGS. 24 to 26 and 4 may then be performed. Accordingly, the semiconductor memory device described above using FIGS. 4 and 32 may be fabricated.

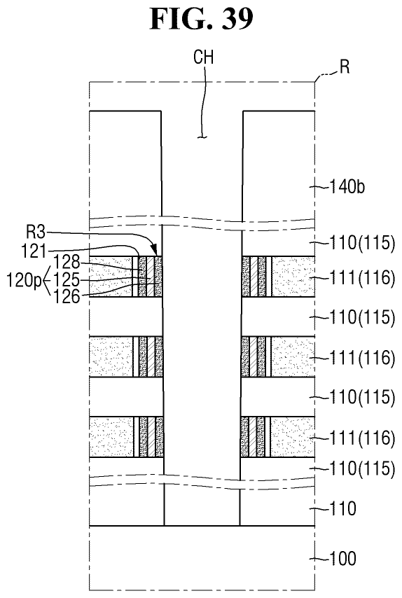

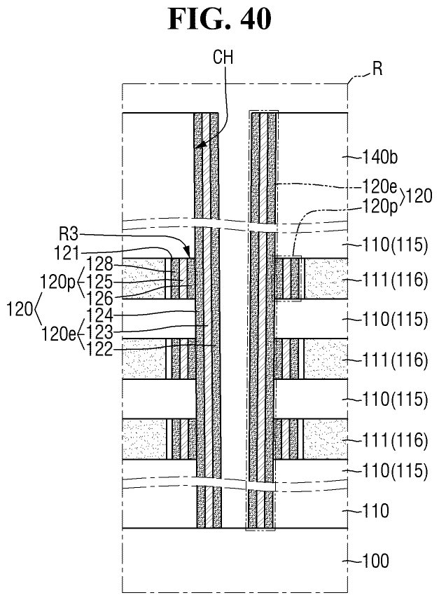

FIGS. 39 and 40 are cross-sectional views illustrating a method for fabricating a semiconductor memory device according to some embodiments. For convenience of explanation, repeated parts of those described above using FIGS. 1 to 38 will be briefly explained or omitted. FIG. 39 is a cross-sectional view illustrating process steps after FIG. 35.

Referring to FIG. 39, a protrusion part 120p which fills third recess R3 that remains after forming the dielectric layer 121 is formed. For example, the fourth ferroelectric layer 128, the second antiferroelectric layer 125 and the third ferroelectric layer 126 may be sequentially formed on the dielectric layer 121 to fill the third recess R3.

Referring to FIG. 40, an extension part 120e is formed along the channel hole CH. The second ferroelectric layer 124, the first antiferroelectric layer 123 and the first ferroelectric layer 122 may be sequentially formed along the channel hole CH. As a result, the insertion layer 120 including the protrusion part 120p and the extension part 120e may be formed.

The process steps described above using FIGS. 37, 38, 24 to 26 and 4 may then be performed. Accordingly, the semiconductor memory device described above using FIGS. 4 and 33 may be fabricated.

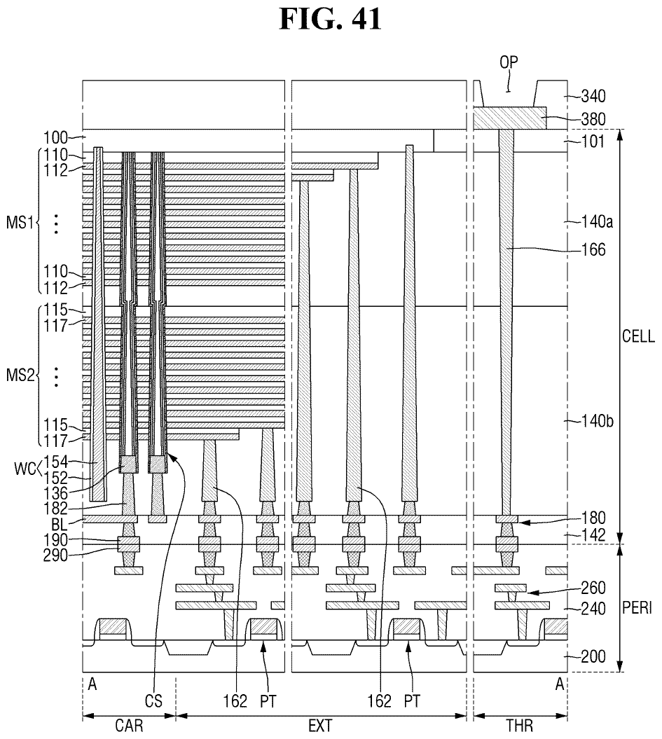

FIG. 41 is a cross-sectional view for explaining a semiconductor memory device according to some embodiments. For convenience of explanation, repeated parts of contents explained above using FIGS. 1 to 5 will be briefly explained or omitted.

Referring to FIG. 41, A cell structure CELL may be substantially equivalent to the cell structure CELL described above. However, the cell structure CELL may have a pad opening OP additionally in FIG. 41. The cell structure CELL and the peripheral circuit structure PERI are connected to each other in different ways as described below.

It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The semiconductor memory device, according to some embodiments, may have a C2C (chip to chip) structure. The C2C structure may mean a structure in which an upper chip including a cell structure CELL is fabricated on a first wafer (e.g., the cell substrate 100) and a lower chip including a peripheral circuit structure PERI is fabricated on a second wafer (e.g., the peripheral circuit substrate 200) different from the first wafer. The upper chip may be turned upside down, and then the overturned upper chip may be connected to the lower chip by a bonding process.

As an example, the bonding process may mean a way of electrically connecting a first bonding metal 190, which is formed on the uppermost metal layer of the upper chip, to a second bonding metal 290 formed on the uppermost metal layer of the lower chip. For example, when the first bonding metal 190 and the second bonding metal 290 are formed of copper (Cu), they may be bonded to each other by a Cu—Cu bonding technique. However, this is only an example, and the first bonding metal 190 and the second bonding metal 290 may, of course, be formed of various other metals such as aluminum (Al) or tungsten (W).

As the first bonding metal 190 and the second bonding metal 290 are bonded, the cell wiring structure 180 may be connected to the peripheral circuit wiring structure 260. Therefore, the bit line BL, the gate electrodes 112 and 117 and/or the cell substrate 100 may be electrically connected to the peripheral circuit element PT.

In some embodiments, an I/O wiring structure 380 may be formed on the back side of the cell substrate 100. The number of layers, placement, and the like of the shown I/O wiring structure 380 are merely examples, and are not limited thereto. The I/O wiring structure 380 may be electrically connected to the cell structure CELL and/or the peripheral circuit structure PERI.

In some embodiments, a through plug 166 may connect the cell wiring structure 180 and the I/O wiring structure 380. The through plug 166 may be formed on the through region THR. The through plug 166 may extend, for example, in the third direction Z and penetrate the third interlayer insulating film 340, the insulating substrate 101, the first interlayer insulating film 140a and the second interlayer insulating film 140b. The cell wiring structure 180 may be electrically connected to the I/O wiring structure 380 through the through plug 166.

In some embodiments, a capping insulating film 342 that covers the I/O wiring structure 380 may be formed. The capping insulating film 342 may include, for example, the pad opening OP that exposes a part of the I/O wiring structure 380. A part of the I/O wiring structure 380 exposed by the pad opening OP may be provided as an I/O pad.

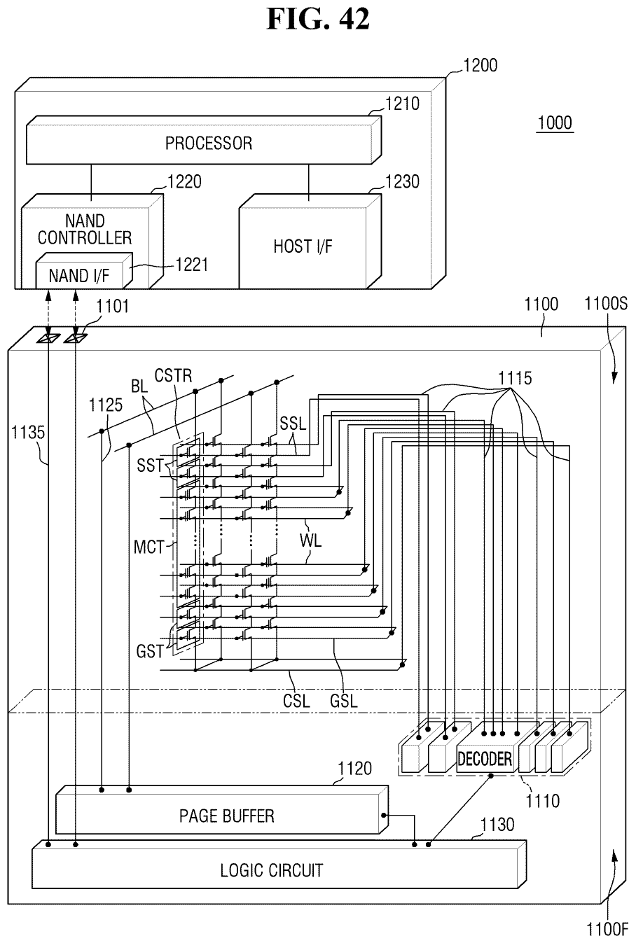

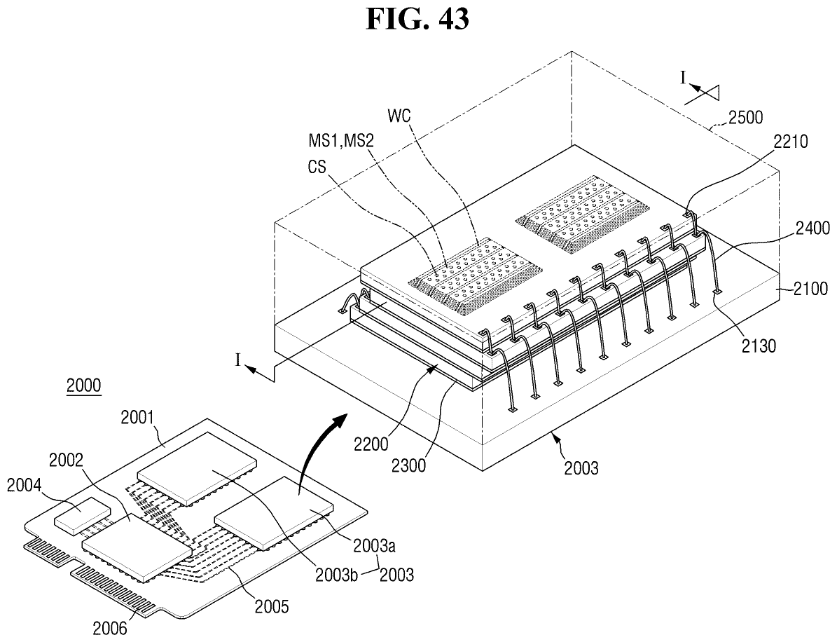

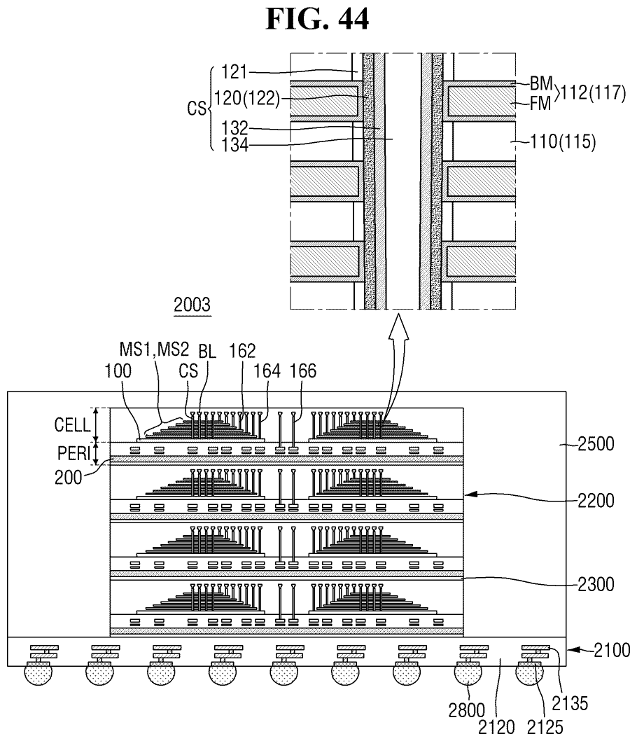

FIG. 42 is an exemplary block diagram for explaining an electronic system according to some embodiments. FIG. 43 is an exemplary perspective view for explaining the electronic system according to some embodiments. FIG. 44 is a schematic cross-sectional view taken along I-I of FIG. 43.

Referring to FIG. 42, an electronic system 1000 (also designated as 2000 in FIG. 43) according to some embodiments may include a semiconductor memory device 1100 (e.g., 10 n FIG. 1), and a controller 1200 that is electrically connected to the semiconductor memory device 1100. The electronic system 1000 may be a storage device that includes one or multiple semiconductor memory devices 1100, or an electronic device that includes the storage device. For example, the electronic system 1000 may be an SSD device (solid state drive device), a USB (Universal Serial Bus), a computing system, a medical device or a communication device that includes one or multiple semiconductor memory devices 1100.

The semiconductor memory device 1100 may be a non-volatile memory device (e.g., a NAND flash memory device), and may be, for example, the semiconductor memory device explained above using FIGS. 1 to 13, 32 and 33. The semiconductor memory device 1100 may include a first structure 1100F and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may correspond to, for example, the peripheral circuit structure PERI explained above using FIGS. 1 to 5.

The second structure 1100S may include the common source line CSL, a plurality of bit lines BL and a plurality of cell strings CSTR explained above using FIG. 2. The cell strings CSTR may be connected to the decoder circuit 1110 through the word line WL, at least one string selection line SSL and at least one ground selection line GSL. In addition, the cell strings CSTR may be connected to the page buffer 1120 through the bit lines BL. The second structure 1100S may correspond to, for example, the cell structure CELL explained above using FIGS. 1 to 13, 32 and 33.

In some embodiments, the common source line CSL and the cell strings CSTR may be electrically connected to the decoder circuit 1110 through first connection wirings 1115 extending from the first structure 1100F to the second structure 1100S. The first connection wiring 1115 may correspond to, for example, a part of the through plug 166 explained above using FIGS. 1 to 5.

In some embodiments, the bit lines BL may be electrically connected to the page buffer 1120 through the second connection wiring 1125. The second connection wiring 1125 may correspond to, for example, another part of the through plugs 166 explained above using FIGS. 1 to 5.

The semiconductor memory device 1100 may communicate with the controller 1200 through an I/O pad 1101 (also designated as 2210 in FIG. 43) electrically connected to the logic circuit 1130 (e.g., the control logic 37 of FIG. 1). The I/O pad 1101 may be electrically connected to the logic circuit 1130 through the I/O connection wiring 1135 extending from the inside of the first structure 1100F to the second structure 1100S.

The controller 1200 may include a processor 1210, a NAND controller 1220 and a host interface 1230. In some embodiments, the electronic system 1000 may include a plurality of semiconductor memory devices 1100, and in this case, the controller 1200 may control the plurality of semiconductor memory devices 1100.

The processor 1210 may control the operation of the electronic system 1000 including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 43 and 44, an electronic system according to some embodiments may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of fins coupled to an external host. In the connector 2006, the number and placement of the plurality of fins may vary depending on the communication interface between the electronic system 2000 and the external host. In some embodiments, the electronic system 2000 may communicate with the external host according to any one of interfaces such as M-Phy for USB (Universal Serial Bus), PCI-Express (Peripheral Component Interconnect Express), SATA (Serial Advanced Technology Attachment) and UFS (Universal Flash Storage). In some embodiments, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 placed on the lower sides of each of the semiconductor chips 2200, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an I/O pad 2210. The I/O pad 2210 may correspond to the I/O pad 1101 of FIG. 28.

In some embodiments, the connecting structure 2400 may be a bonding wire that electrically connects the I/O pad 2101 and the package upper pads 2130. Therefore, in each of the first semiconductor package 2003a and the second semiconductor package 2003b, the semiconductor chips 2200 may be electrically connected to each other by a bonding wire type, and may be electrically connected to the package upper pads 2130 of the package substrate 2100. In some embodiments, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire type.

In some embodiments, the main controller 2002 and the semiconductor chips 2200 may also be included in a single package. In some embodiments, the main controller 2002 and the semiconductor chips 2200 are mounted on a separate interposer substrate different from the main board 2001, and the main controller 2002 and the semiconductor chips 2200 may also be connected to each other by wiring formed on the interposer substrate.

In some embodiments, the package substrate 2100 may be a printed circuit board. The package substrate 2100 may include a package substrate body portion 2120, package upper pads 2130 placed on an upper side of the package substrate body portion 2120, package lower pads 2125 placed on a lower side of the package substrate body portion 2120 or exposed through the lower side, and inner wirings 2135 that electrically connect the package upper pads 2130 and the package lower pads 2125 inside the package substrate body portion 2120. The package upper pads 2130 may be electrically connected to the connecting structures 2400. The package lower pads 2125 may be connected to the wiring patterns 2005 of the main board 2001 of the electronic system 2000 through conductive connections 2800 as in FIG. 44.

In the electronic system according to some embodiments, each of the semiconductor chips 2200 may include the semiconductor memory device described above using FIGS. 1 to 13, 32 and 33. For example, each of the semiconductor chips 2200 may include a peripheral circuit structure PERI and a cell structure CELL stacked on the peripheral circuit structure PERI. As an example, the peripheral circuit structure PERI may include the peripheral circuit substrate 200 and the peripheral circuit wiring structure 260 explained above using FIGS. 3 and 4. Further, as an example, the cell structure CELL may include the cell substrate 100, the first and second mold stacks MS1 and MS2, the channel structure CH, the bit line BL, the gate contact 162, the second substrate contact 164, and the through plug 166 explained above using FIGS. 3 and 4. The channel structure CH may also include the dielectric layer 121, the insertion layer 120, the channel layer 132, and the core insulating layer 134 explained above using FIGS. 5 to 13, 32 and 33.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor memory device comprising:
a substrate;
a mold stack formed on the substrate, the mold stack including gate electrodes and mold insulating films alternately stacked on the substrate;
a channel layer that extends through the mold stack in a vertical direction intersecting an upper surface of the substrate;
an insertion layer that surrounds the channel layer, the insertion layer including ferroelectrics; and
a dielectric layer interposed between the insertion layer and the mold insulating films,
wherein the gate electrodes are in contact with the insertion layer.

2. The semiconductor memory device of claim 1, wherein an etching rate of the dielectric layer is different from an etching rate of the mold insulating films in an etching process.

3. The semiconductor memory device of claim 1, wherein:
the insertion layer includes a first ferroelectric layer extending in the vertical direction; and
the gate electrodes are in contact with the first ferroelectric layer.

4. The semiconductor memory device of claim 3, wherein a portion of each of the gate electrodes extends into an interior of the first ferroelectric layer.

5. The semiconductor memory device of claim 1, wherein:
the insertion layer includes a first ferroelectric layer, a metal layer, and a second ferroelectric layer that are sequentially stacked on a side face of the channel layer;
the first ferroelectric layer extends in the vertical direction;
the metal layer and the second ferroelectric layer are disposed at positions corresponding to the gate electrodes; and
the gate electrodes are in contact with the second ferroelectric layer.

6. The semiconductor memory device of claim 1, wherein:
the insertion layer includes a first ferroelectric layer and a first antiferroelectric layer that are sequentially stacked on a side face of the channel layer; and
the gate electrodes are in contact with the first antiferroelectric layer.

7. The semiconductor memory device of claim 6, wherein the first ferroelectric layer and the first antiferroelectric layer extend along the side face of the channel layer.

8. The semiconductor memory device of claim 1, wherein:
the insertion layer includes a first ferroelectric layer, a first antiferroelectric layer, and a second ferroelectric layer which are stacked sequentially on a side face of the channel layer;
the first ferroelectric layer extends in the vertical direction;
the second ferroelectric layer is disposed at a position corresponding to the gate electrodes; and
the gate electrodes are in contact with the second ferroelectric layer.

9. The semiconductor memory device of claim 1, wherein the insertion layer further extends along and contacts a portion of the upper surface of the substrate.

10. The semiconductor memory device of claim 1, wherein the gate electrodes protrude toward the channel layer beyond the mold insulating films.

11. The semiconductor memory device of claim 1, wherein the mold insulating films protrude toward the channel layer beyond the gate electrodes.

12. The semiconductor memory device of claim 1, wherein the mold insulating films include an air gap.

13. The semiconductor memory device of claim 1, wherein the channel layer includes an n-type channel layer and a p-type channel layer.

14. A semiconductor memory device comprising:
a substrate;
a mold stack formed on the substrate, the mold stack including gate electrodes and mold insulating films alternately stacked on the substrate;
a channel layer which extends through the mold stack in a vertical direction intersecting an upper surface of the substrate; and
an insertion layer which includes an extension part extending in the vertical direction along a side face of the channel layer and a plurality of protrusion parts protruding from the extension part toward each corresponding one of the gate electrodes,
wherein the extension part and the plurality of protrusion parts each include a ferroelectric material.

15. The semiconductor memory device of claim 14, further comprising:
a dielectric layer,
wherein the dielectric layer is interposed between the plurality of protrusion parts and the gate electrodes, and the dielectric layer is disposed at positions corresponding to the gate electrodes.

16. The semiconductor memory device of claim 14, wherein the insertion layer includes ferroelectric layers and metal layers which are alternately stacked on the side face of the channel layer.

17. The semiconductor memory device of claim 14, wherein the extension part of the insertion layer and the plurality of protrusion parts each include at least one ferroelectric layer and at least one antiferroelectric layer.

18. The semiconductor memory device of claim 14, wherein each of the extension part of the insertion layer and the plurality of protrusion parts of the insertion layer includes a plurality of ferroelectric layers and a plurality of antiferroelectric layers alternately stacked on the side face of the channel layer.

19. An electronic system comprising:
a main board;
a semiconductor memory device on the main board; and
a controller which is electrically connected to the semiconductor memory device, the controller disposed on the main board,
wherein the semiconductor memory device includes:
a substrate,
a mold stack formed on the substrate, the mold stack including gate electrodes and mold insulating films alternately stacked on the substrate,
a channel layer which extends through the mold stack in a vertical direction intersecting an upper surface of the substrate,
an insertion layer surrounds the channel layer, the insertion layer includes ferroelectrics, and
a dielectric layer interposed between the insertion layer and the mold insulating films,
wherein:
the dielectric layer is disposed at positions corresponding to the gate electrodes; and
the gate electrodes are in contact with the insertion layer.

20. The electronic system of claim 19, wherein the dielectric layer includes at least one of titanium oxide, hafnium oxide, zirconium oxide, silicon oxide, and aluminum oxide.
